(19) United States
(12) Patent Application Publication
(10) Pub. No.: US 2026/0354223 A1
(43) Pub. Date: Nov. 5, 2026

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Po-Ching Wu, Hsinchu (TW); Meng-Tsan Lee, Hsinchu (TW); Li-Han Hsu, Hsinchu (TW); An-Jhih Su, Taoyuan City (TW)

(21) Appl. No.: 19/742,591

(22) Filed: Jul. 15, 2026

Related U.S. Application Data
(63) Continuation of application No. 19/175,556, filed on Apr. 10, 2025.
(60) Provisional application No. 63/723,681, filed on Nov. 22, 2024.

(51) Int. Cl. H10W 70/60; H10W 70/00; H10W 70/05; H10W 70/65; H10W 70/68; H10W 70/692; H10W 74/01; H10W 90/00; H10B 80/00; H10D 80/30; H10P 72/70; H10W 72/00; H10W 72/29; H10W 74/15

(52) U.S. Cl. CPC H10W 70/611; H10W 70/095; H10W 70/099; H10W 70/65; H10W 70/68; H10W 70/692; H10W 74/016; H10W 90/401; H10B 80/00; H10D 80/30; H10P 72/7402; H10W 72/0198; H10W 72/29; H10W 74/15; H10W 90/00; H10W 90/724; H10W 90/734; H10W 90/792

(57) ABSTRACT

A method includes forming a package component, the package component comprising: an interposer comprising a first redistribution structure; integrated circuit dies attached to the first redistribution structure; forming a package substrate, forming the package substrate comprising: forming a second redistribution structure and a third redistribution structure over opposite sides of a substrate core; singulating the substrate core to form component substrates; attaching a first component substrate and a second component substrate to a carrier, the first component substrate and the second component substrate being laterally displaced by a gap; and forming a bonding layer over the first component substrate and the second component substrate; attaching the package component to the package substrate; and forming external connectors over the package substrate, the external connectors being configured to electrically couple a signal routing, a power routing, or a ground routing of the integrated circuit dies to an another package component.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an integrated circuit die, in accordance with some embodiments.

FIGS. 2A-2B are cross-sectional views of die stacks, in accordance with some embodiments.

FIGS. 3-16 are cross-sectional views of intermediate stages in the manufacturing of an integrated circuit package, in accordance with some embodiments.

FIGS. 17-22 are cross-sectional views of intermediate stages in the manufacturing of an integrated circuit package, in accordance with some embodiments.

FIGS. 23-24 are cross-sectional views of various integrated circuit packages, in accordance with some other embodiments.

FIGS. 25-33 are cross-sectional views of intermediate stages in the manufacturing of an integrated circuit package, in accordance with some embodiments.

FIG. 34 is a plan view of an integrated circuit package, in accordance with some other embodiments.

FIGS. 35-37 are cross-sectional views of various integrated circuit packages, in accordance with some other embodiments.

FIG. 38 is a plan view of an integrated circuit package, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, an integrated circuit package includes one or more package components attached and electrically connected to a package substrate. For example, the package components may include an integrated circuit die, a plurality of integrated circuit dies bonded to an interposer (e.g., a chip on wafer), and/or a plurality of stacked chips (e.g., a system on integrated chip). In particular, one or more redistribution structures are formed over a substrate core in wafer form. The substrate core is then singulated into distinct component substrates, and a plurality of the singulated component substrates are adhered to a carrier with gaps between adjacent component substrates. A gap-filling material is then applied to fill the gaps to form a reconstituted package substrate. The reconstituted package substrate may be further processed, such as forming a redistribution structure, attaching interconnection dies, and/or forming metal pillars. Notwithstanding this further processing, the resulting reconstituted package substrate experiences less warpage than the substrate core and redistribution structures in wafer form prior to singulation. As such, the integrated circuit package may have a larger footprint (e.g., reconstituted package substrate) which supports larger reticles and/or a greater number of reticles of the package components. The integrated circuit packages according to the embodiments discussed herein may include greater package substrate sizes with less warpage, which improves performance, reliability, and longevity. In addition, the integrated circuits may have improved electrical connectivity between a variety of package components (e.g., types of package components or varying technology nodes).

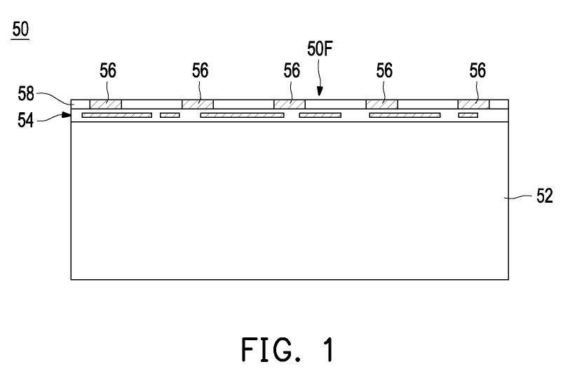

FIG. 1 is a cross-sectional view of an integrated circuit die 50. Multiple integrated circuit dies 50 will be packaged in subsequent processing to form integrated circuit packages. Each integrated circuit die 50 may be a logic die (e.g., central processing unit (CPU), graphics processing unit (GPU), system-on-a-chip (SoC) die, microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. The integrated circuit die 50 may be formed in a wafer, which may include different die regions that are singulated in subsequent steps to form a plurality of integrated circuit dies 50. The integrated circuit die 50 includes a semiconductor substrate 52, an interconnect structure 54, die connectors 56, and a dielectric layer 58.

The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) are at the active surface of the semiconductor substrate 52. The devices may be active devices (e.g., transistors, diodes, etc.), capacitors, resistors, etc. The inactive surface may be free from devices.

The interconnect structure 54 is over the active surface of the semiconductor substrate 52, and is used to electrically connect the devices of the semiconductor substrate 52 together to form an integrated circuit. The interconnect structure 54 may include one or more dielectric layer(s) and respective metallization layer(s) in the dielectric layer(s). Acceptable dielectric materials for the dielectric layers include oxides such as silicon oxide or aluminum oxide, nitrides such as silicon nitride, combinations thereof such as silicon oxynitride, or the like. Other dielectric materials may also be used, such as a polymer, such as polybenzoxazole (PBO), polyimide, a benzocyclobuten (BCB) based polymer, or the like. The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Die connectors 56 are at the front-side 50F of the integrated circuit die 50. The die connectors 56 may be conductive pillars, pads, or the like, to which external connections are made. The die connectors 56 are in and/or on the interconnect structure 54. For example, the die connectors 56 may be part of an upper metallization layer of the interconnect structure 54. The die connectors 56 may be formed of a metal, such as copper, aluminum, or the like, and may be formed by, for example, plating, or the like.

Optionally, solder regions (not separately illustrated) may be disposed on the die connectors 56 during formation of the integrated circuit die 50. The solder regions may be used to perform chip probe (CP) testing on the integrated circuit die 50. For example, the solder regions may be solder balls, solder bumps, or the like, which are used to attach a chip probe to the die connectors 56. Chip probe testing may be performed on the integrated circuit die 50 to ascertain whether the integrated circuit die 50 is a known good die (KGD). Thus, only integrated circuit dies 50, which are KGDs, undergo subsequent processing and are packaged, and dies which fail the chip probe testing are not packaged. After testing, the solder regions may be removed.

A dielectric layer 58 is at the front-side 50F of the integrated circuit die 50. The dielectric layer 58 is in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a polymer, the like, or a combination thereof, which may be formed, for example, by spin coating, lamination, chemical vapor deposition (CVD), or the like. Front-side surfaces of the die connectors 56 and the dielectric layer 58 may be substantially coplanar (within process variations) at the front-side 50F of the integrated circuit die 50.

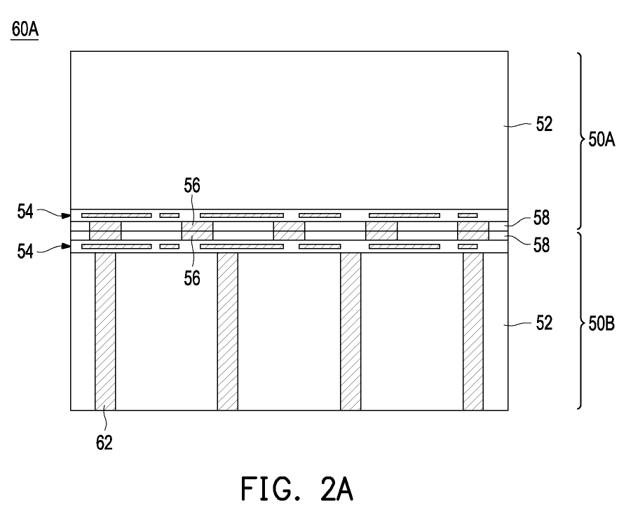

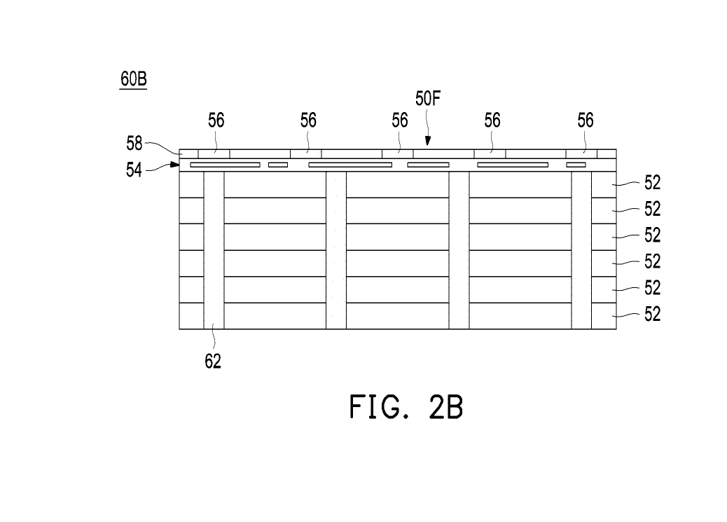

FIGS. 2A and 2B are cross-sectional views of die stacks 60A, 60B, respectively. The die stacks 60A, 60B may each have a single function (e.g., a logic device, memory die, etc.), or may have multiple functions. In some embodiments, the die stack 60A is a logic device such as a system-on-integrated-chip (SoIC) device and the die stack 60B is a memory device such as high bandwidth memory (HBM) device.

As shown in FIG. 2A, the die stack 60A includes two bonded integrated circuit dies 50 (e.g., a first integrated circuit die 50A and a second integrated circuit die 50B). In some embodiments, the first integrated circuit die 50A is a logic die, and the second integrated circuit die 50B is an interface die. An interface die bridges a logic die to other package components such as memory dies, and translates commands between the logic die and integrated circuits of the other package components (e.g., the memory dies). In some embodiments, the first integrated circuit die 50A and the second integrated circuit die 50B are bonded such that the active surfaces are facing each other (e.g., are “face-to-face” bonded). Conductive vias 62 may be formed through one of the integrated circuit dies 50 so that external connections may be made to the die stack 60A. The conductive vias 62 may be through substrate vias (TSVs), such as through-silicon vias or the like. In the illustrated embodiment, the conductive vias 62 are formed in the second integrated circuit die 50B (e.g., the interface die). The conductive vias 62 extend through the semiconductor substrate 52 of the respective integrated circuit die 50, to be physically and electrically connected to the metallization layer(s) of the interconnect structure 54.

As shown in FIG. 2B, the die stack 60B is a stacked device that includes multiple semiconductor substrates 52. For example, the die stack 60B may be a memory device that includes multiple memory dies such as a hybrid memory cube (HMC) device, a high bandwidth memory (HBM) device, or the like. Each semiconductor substrate 52 may (or may not) have a separate interconnect structure 54. The semiconductor substrates 52 are connected by conductive vias 62, such as TSVs.

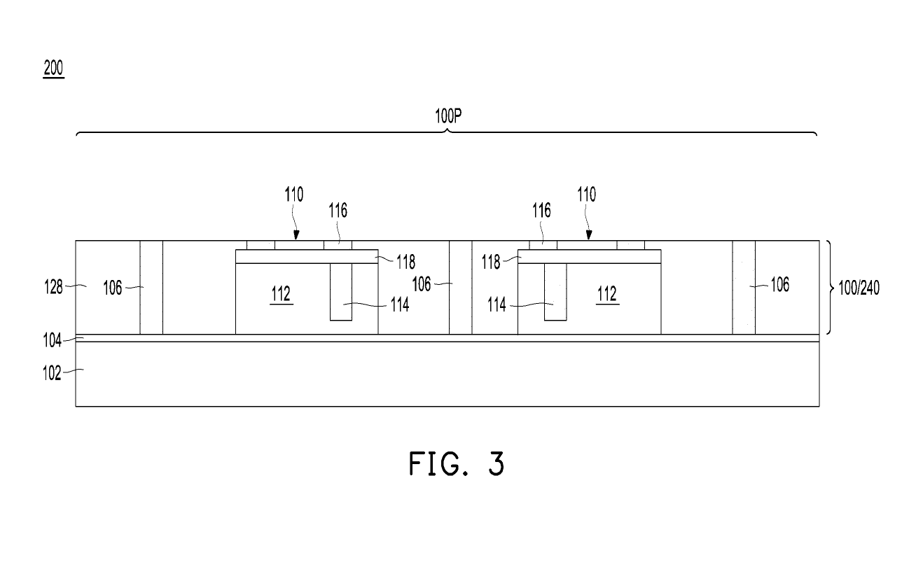

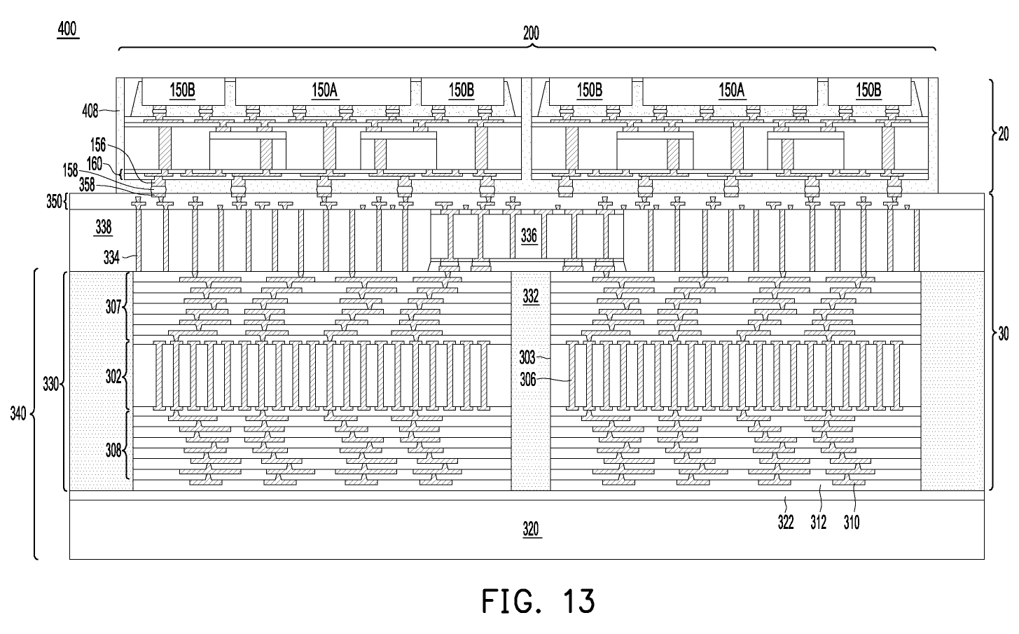

FIGS. 3-16 are views of intermediate stages in the manufacturing of an integrated circuit package 400 (see FIGS. 13-16), in accordance with some embodiments. FIGS. 3-5 illustrate the formation of a package component 200. For example, a package region 100P of an interposer wafer 100 is illustrated, and the package component 200 is formed in the package region 100P. Although a single package region 100P is illustrated, it should be appreciated that multiple package regions 100P may be formed. For example, the interposer wafer 100 is formed to include an interposer 240 in the package region 100P. Integrated circuit devices 150 are attached to the interposer 240. The interposer 240 may include interconnection dies 110 (e.g., bridge dies) for interconnecting the integrated circuit devices 150 in the package region 100P. The package region 100P may be singulated to form a package component 200.

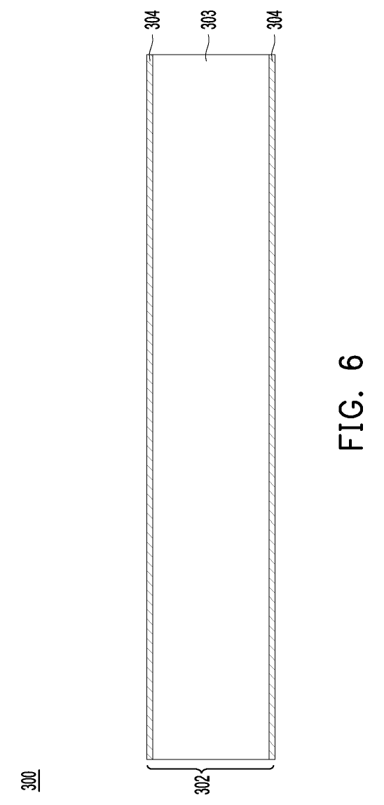

FIGS. 6-12 illustrate the formation of a reconstituted package substrate 300. For example, front side and back side redistribution structures 307, 308 are formed over a core substrate 302, and the structure is singulated to form distinct component substrates 330. A plurality of the singulated component substrates 330 are then formed into a reconstituted package substrate 300. Further processing may then be performed to form a redistribution structure, an interposer layer, and/or interconnection dies over the component substrates.

FIGS. 13-16 illustrate the formation of an integrated circuit package 400 comprising one or more package components 200 and the reconstituted package substrate 300. For example, the package components 200 are attached to the reconstituted package substrate 300. The package substrate 300 is singulated to form the integrated circuit package 400, which includes the singulated package substrate 300 and singulated portions of the interposer wafer 100 (e.g., the interposer 240). In an embodiment, the integrated circuit package 400 is a chip-on-wafer-on-substrate package, wherein one or more integrated circuit chips may be attached to an interposer, which may be attached to a package substrate. For example, such packages may further include integrated circuit chips or dies embedded within the interposer and/or the package substrate. It should be appreciated that embodiments may be applied to other three-dimensional integrated circuit (3DIC) packages.

In FIG. 3, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

Through vias 106 are formed over the release layer 104. It should be appreciated that any desired quantity and arrangement of through vias 106 may be formed. As an example to form the through vias 106, a seed layer (not separately illustrated) is formed over the release layer 104. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as physical vapor deposition (PVD) or the like. A photoresist is then formed and patterned on the seed layer. The photoresist may be formed by spin coating or the like and may be exposed to light for patterning. The pattern of the photoresist corresponds to the through vias 106. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the through vias 106.

Still referring to FIG. 3, interconnection dies 110 are placed on the release layer 104. The interconnection dies 110 may be placed on the release layer 104 using, e.g., a pick-and-place tool. The interconnection dies 110 may be utilized for direct communication between integrated circuit devices (subsequently described) of the integrated circuit package 400.

Each interconnection die 110 may be a local silicon interconnect (LSI), a large scale integration package, an interposer die, or the like. The interconnection dies 110 may be bridge dies. In the illustrated cross-section, two interconnection dies 110 are attached in the package region 100P. It should be appreciated that any desired quantity and arrangement of interconnection dies 110 may be attached in each package region 100P. The interconnection dies 110 may include passive devices such as surface mount devices (SMDs), 2-terminal integrated passive devices (IPDs), multi-terminal IPDs, or the like, or integrated voltage regulators (IVRs).

Each interconnection die 110 includes a substrate 112, with conductive features formed in and/or on the substrate 112. The substrates 112 may include a semiconductor substrate, one or more dielectric layer(s), or the like. Additionally, each interconnection die 110 may include through substrate vias (TSVs) 114 that extend into or through the substrate 112, and may be coupled to the conductive features of the interconnection die 110. In the illustrated embodiment, the substrates 112 initially cover the TSVs 114 at the back-sides of the interconnection dies 110. In another embodiment, the TSVs 114 are exposed at the back-sides of the interconnection dies 110. The interconnection die 110 also includes die connectors 116 disposed at the front-side of the interconnection die 110. Some of the die connectors 116 may be electrically coupled to the back-side of the interconnection die 110 by the TSVs 114. The TSVs 114 may be small, such as smaller than the through vias 106.

In some embodiments, the interconnection dies 110 may include die bridges 118. The die bridges 118 may be metallization layers formed in and/or on, e.g., the substrates 112, and work to interconnect integrated circuit devices (subsequently described) to one another. The die bridges 118 may include interconnects, redistribution lines, or the like. The die bridges 118 are located at the front-side of the interconnection dies 110. As such, the interconnection dies 110 can be used to directly connect and allow communication between integrated circuit devices. In such embodiments, the interconnection dies 110 may be placed in respective regions that are disposed between the subsequently attached integrated circuit devices, so that each interconnection die 110 is overlapped by multiple overlying integrated circuit devices. In some embodiments, the interconnection dies 110 may further include passive devices and/or active devices. In some embodiments, the interconnection dies 110 are substantially free of active devices and passive devices. The interconnection dies 110 may be placed over the carrier substrate 102 such that the die bridges 118 face away from the carrier substrate 102 (e.g., towards the subsequently attached integrated circuit devices).

In further reference to FIG. 3, an encapsulant 128 is formed around the various components. After formation, the encapsulant 128 laterally encapsulates the interconnection dies 110 and the through vias 106. The encapsulant 128 may be a molding compound, epoxy, or the like. The encapsulant 128 may be applied by compression molding, transfer molding, or the like, and may be formed over the carrier substrate 102 such that the interconnection dies 110 and/or the through vias 106 are buried or covered. The encapsulant 128 may be formed in gap regions between the various components. The encapsulant 128 may be applied in liquid or semi-liquid form and then subsequently cured.

A removal process may optionally be performed on the encapsulant 128 to expose the interconnection dies 110 and the through vias 106. The removal process may remove material of the encapsulant 128, the interconnection dies 110, and/or the through vias 106 until the die connectors 116 and the through vias 106 are exposed. The removal process may include, for example, a planarization process such as a chemical-mechanical polish (CMP), a grinding process, or the like. The front-side surfaces of the encapsulant 128, the interconnection dies 110 (e.g., the die connectors 116), and the through vias 106 may be substantially coplanar (within process variations) after the planarization process. The planarization may be omitted, for example, if the through vias 106 and the die connectors 116 are already exposed. After the removal process, the through vias 106 extend through the encapsulant 128. As such, the through vias 106 may be referred to as through-mold vias (TMVs).

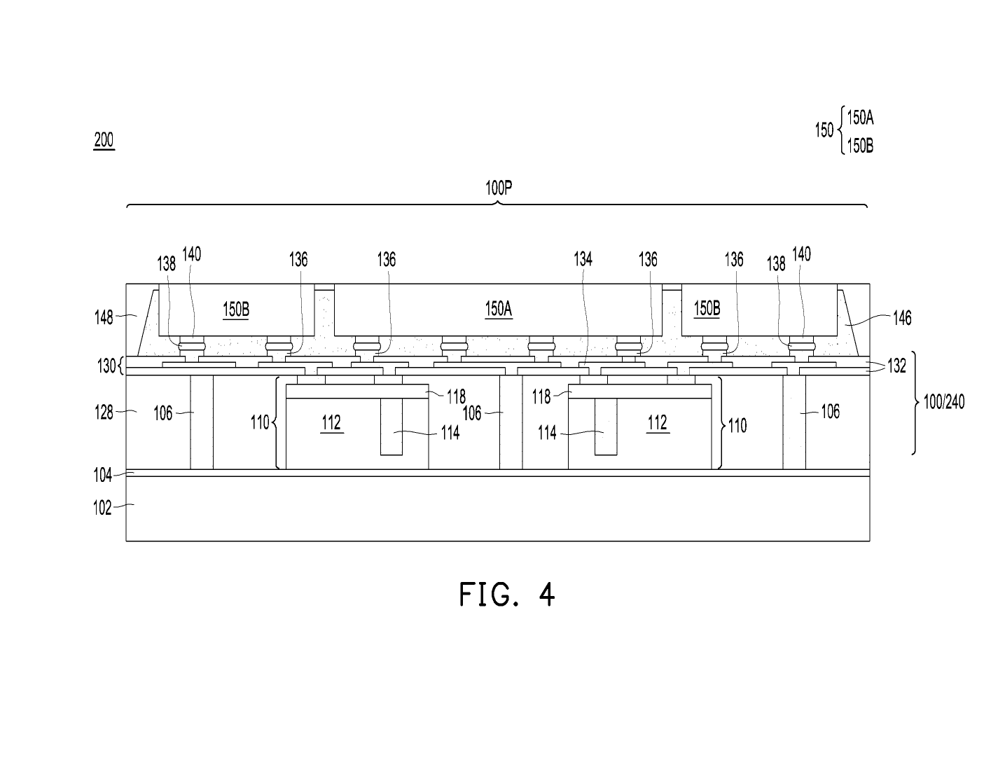

In FIG. 4, a front-side redistribution structure 130 is formed on the front-side surfaces of the encapsulant 128, the interconnection dies 110 (e.g., the die connectors 116), and the through vias 106. The front-side redistribution structure 130 includes dielectric layers 132 and metallization layer(s) 134 (sometimes referred to as redistribution layers or redistribution lines) among the dielectric layers 132. Thus, the front-side redistribution structure 130 includes metallization layer(s) 134 separated from each other by respective dielectric layers 132. The metallization layer(s) 134 of the front-side redistribution structure 130 are connected to the through vias 106 and to the interconnection dies 110 (e.g., the die connectors 116).

In some embodiments, the dielectric layers 132 are formed of a polymer, which may be a photosensitive material such as PBO, polyimide, a BCB-based polymer, or the like, that may be patterned using a lithography mask. In other embodiments, the dielectric layers 132 are formed of a nitride such as silicon nitride, an oxide such as silicon oxide, or the like. The dielectric layers 132 may be formed by spin coating, lamination, CVD, the like, or a combination thereof. After a dielectric layer 132 is formed, it may be patterned to expose underlying conductive features, such as portions of the through vias 106, the die connectors 116, and/or the metallization layer(s) 134. The patterning may be by any acceptable process, such as by exposing the dielectric layers 132 to light when they are formed of photosensitive material, or by etching using, for example, an anisotropic etch. If the dielectric layers 132 are formed of a photosensitive material, the dielectric layers 132 may be developed after the exposure.

The metallization layer(s) 134 each include conductive vias and/or conductive lines. The conductive vias extend through respective dielectric layers 132, and the conductive lines extend along respective dielectric layers 132. As an example to form a metallization layer 134, a seed layer (not separately illustrated) is formed over the respective underlying features. For example, the seed layer may be formed on a respective dielectric layer 132 and in any openings through the respective dielectric layer 132. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 134. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 134 of the front-side redistribution structure 130.

The front-side redistribution structure 130 is illustrated as an example. More or fewer dielectric layers 132 and metallization layer(s) 134 than illustrated may be formed by performing the previously described steps any desired quantity of times.

Other variations of the front-side redistribution structure 130 are contemplated. For example, some of the dielectric layers 132 may be formed of an encapsulant, such as a molding compound, epoxy, or the like. A metallization layer 134 may be formed by plating a conductive via from a conductive line. A dielectric layer 132 may be formed by encapsulating that metallization layer 134. Any desired stack of materials may be used for the dielectric layers 132.

Under-bump metallizations (UBMs) 136 may be formed through the upper dielectric layer 132 of the front-side redistribution structure 130. The UBMs 136 are physically and electrically coupled to the upper metallization layer 134 of the front-side redistribution structure 130. The UBMs 136 each include conductive vias and conductive bumps. The conductive vias extend through the upper dielectric layer 132, and the conductive bumps extend along the upper dielectric layer 132. The UBMs 136 may be formed of the same material(s) as the metallization layer(s) 134. In some embodiments, the UBMs 136 have a different size than the metallization layer(s) 134.

Still referring to FIG. 4, integrated circuit devices 150 are attached to the front-side redistribution structure 130. Multiple integrated circuit devices 150 are placed adjacent one another in the package region 100P. The integrated circuit devices 150 in each package region 100P may include logic devices 150A and memory devices 150B. Although the illustrated cross-section shows a single logic device 150A and two memory devices 150B, it should be appreciated that any quantity of multiple logic devices 150A (e.g., more than one) and memory devices 150B may be attached. The logic devices 150A and the memory devices 150B may be formed in processes of a same technology node, or may be formed in processes of different technology nodes. For example, the logic devices 150A may be formed by a more advanced process node than the memory devices 150B.

Each logic device 150A may be a central processing unit (CPU), graphics processing unit (GPU), system-on-a-chip (SoC), microcontroller, or the like. The logic devices 150A may be integrated circuit dies (similar to the integrated circuit die 50 described for FIG. 1) or may be die stacks (similar to the die stack 60A described for FIG. 2A). In some embodiments, the logic devices 150A are integrated circuit dies such as system-on-a-chip (SoC) dies. In some embodiments, the logic devices 150A are die stacks such as system-on-integrated-chip (SoIC) devices.

Each memory device 150B may be a dynamic random access memory (DRAM) die, static random access memory (SRAM) die, hybrid memory cube (HMC) module, a high bandwidth memory (HBM) module, or the like. The memory devices 150B may be integrated circuit dies (similar to the integrated circuit die 50 described for FIG. 1) or may be die stacks (similar to the die stack 60B described for FIG. 2B). In some embodiments, the memory devices 150B are die stacks, such as high bandwidth memory (HBM) devices.

In the illustrated embodiment, the integrated circuit devices 150 are attached to the front-side redistribution structure 130 with solder bonds, such as with conductive connectors 138. The conductive connectors 138 may be formed of a conductive material that is reflowable, such as solder, copper, aluminum, gold, nickel, silver, palladium, tin, the like, or a combination thereof. In some embodiments, the conductive connectors 138 are formed by initially forming a layer of solder through methods such as evaporation, electroplating, printing, solder transfer, ball placement, or the like. Once a layer of solder has been formed on the structure, a reflow may be performed in order to shape the conductive connectors 138 into desired bump shapes. Attaching the integrated circuit devices 150 to the front-side redistribution structure 130 may include placing the integrated circuit devices 150 on the front-side redistribution structure 130 and reflowing the conductive connectors 138. The integrated circuit devices 150 may be placed on the front-side redistribution structure 130 using, e.g., a pick-and-place tool. The conductive connectors 138 are reflowed to attach die connectors 140 at the front-sides of the integrated circuit devices 150 to the UBMs 136 of the front-side redistribution structure 130, thereby electrically connecting the front-side redistribution structure 130 to the integrated circuit devices 150. In another embodiment, the integrated circuit devices 150 are attached to the front-side redistribution structure 130 with direct bonds, using the die connectors 140.

In further reference to FIG. 4, an underfill 146 is formed around the conductive connectors 138, and between the front-side redistribution structure 130 and the integrated circuit devices 150. The underfill 146 may reduce stress and protect the joints resulting from the reflowing of the conductive connectors 138. The underfill 146 may be formed of an underfill material such as a molding compound, epoxy, or the like. The underfill 146 may be formed by a capillary flow process after the integrated circuit devices 150 are attached to the front-side redistribution structure 130, or may be formed by a suitable deposition method before the integrated circuit devices 150 are attached to the front-side redistribution structure 130. The underfill 146 may be applied in liquid or semi-liquid form and then subsequently cured.

An encapsulant 148 is formed around the various components. After formation, the encapsulant 148 laterally encapsulates the underfill 146 (if present) and the integrated circuit devices 150. The encapsulant 148 may be a molding compound, epoxy, or the like. The encapsulant 148 may be applied by compression molding, transfer molding, or the like, and may be formed over the front-side redistribution structure 130 such that the integrated circuit devices 150 are buried or covered. The encapsulant 148 is further formed in gap regions between the underfill 146 (if present) and/or the integrated circuit devices 150. The encapsulant 148 may be applied in liquid or semi-liquid form and then subsequently cured.

A removal process may optionally be performed on the encapsulant 148 to expose the integrated circuit devices 150. The removal process may include, for example, a planarization process such as a chemical-mechanical polish (CMP), a grinding process, or the like. The top surfaces of the encapsulant 148 and the integrated circuit devices 150 may be substantially coplanar (within process variations) after the planarization process. The planarization may be omitted, for example, if the integrated circuit devices 150 are already exposed.

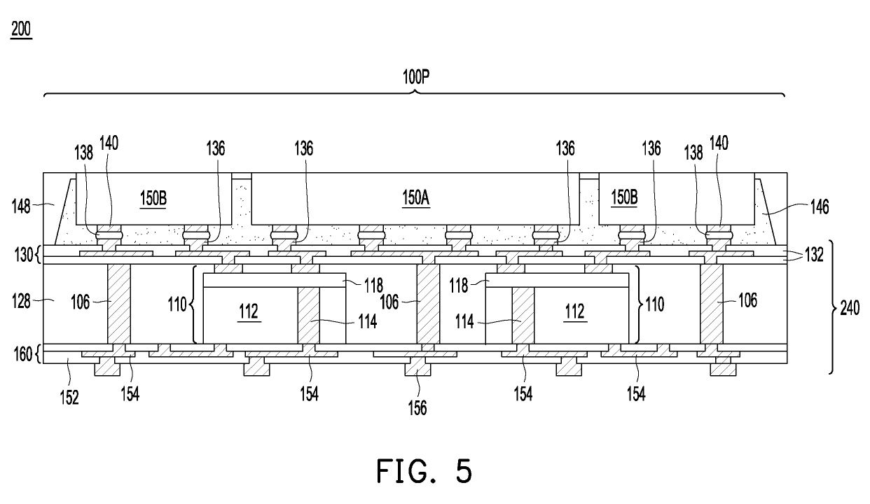

In FIG. 5, a carrier substrate de-bonding is performed to detach (or “de-bond”) the carrier substrate 102 from the interposer wafer 100, and a back-side redistribution structure 160 is formed. In accordance with some embodiments, the de-bonding includes projecting a light such as a laser light or an UV light on the release layer 104 so that the release layer 104 decomposes under the heat of the light and the carrier substrate 102 can be removed. The interposer wafer 100 is then flipped over to prepare for processing of the back-side of the interposer wafer 100. The interposer wafer 100 may be placed on a tape, a carrier substrate, or another suitable support structure (not separately illustrated) for subsequent processing. Note that the interposer wafer 100 may also be referred to as a reconstructed wafer.

A removal process may optionally be performed on the substrates 112 and the encapsulant 128 to expose the through vias 106 and the TSVs 114. The removal process may remove material of the encapsulant 128, the interconnection dies 110 (e.g., the substrates 112 and the TSVs 114), and/or the through vias 106 until the TSVs 114 and the through vias 106 are exposed. The removal process may include, for example, a planarization process such as a chemical-mechanical polish (CMP), a grinding process, or the like. The back-side surfaces of the encapsulant 128, the interconnection dies 110 (e.g., the substrates 112 and the TSVs 114), and the through vias 106 may be substantially coplanar (within process variations) after the planarization process.

As illustrated, the back-side redistribution structure 160 is formed on the back-side surfaces of the encapsulant 128, the interconnection dies 110 (e.g., the substrates 112 and the TSVs 114), and the through vias 106. The back-side redistribution structure 160 includes dielectric layers 152 and metallization layer(s) 154 (sometimes referred to as redistribution layers or redistribution lines) among the dielectric layers 152. Thus, the back-side redistribution structure 160 includes metallization layer(s) 154 separated from each other by respective dielectric layers 152. The metallization layer(s) 154 of the back-side redistribution structure 160 are connected to the through vias 106 and to the interconnection dies 110 (e.g., the TSVs 114).

In some embodiments, the dielectric layers 152 are formed of a polymer, which may be a photosensitive material such as PBO, polyimide, a BCB-based polymer, or the like, that may be patterned using a lithography mask. In other embodiments, the dielectric layers 152 are formed of a nitride such as silicon nitride, an oxide such as silicon oxide, or the like. The dielectric layers 152 may be formed by spin coating, lamination, CVD, the like, or a combination thereof. After a dielectric layer 152 is formed, it may be patterned to expose underlying conductive features, such as portions of the through vias 106, the TSVs 114, and/or the metallization layer(s) 154. The patterning may be by any acceptable process, such as by exposing the dielectrics layers to light when they are formed of photosensitive material, or by etching using, for example, an anisotropic etch. If the dielectric layers 152 are formed of a photosensitive material, the dielectric layers 152 may be developed after the exposure.

The metallization layer(s) 154 each include conductive vias and/or conductive lines. The conductive vias extend through respective dielectric layers 152, and the conductive lines extend along respective dielectric layers 152. As an example to form a metallization layer 154, a seed layer (not separately illustrated) is formed over the respective underlying features. For example, the seed layer may be formed on a respective dielectric layer 152 and in any openings through the respective dielectric layer 152. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The pattern of the photoresist corresponds to the metallization layer 154. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form a metallization layer 154 of the back-side redistribution structure 160.

The back-side redistribution structure 160 is illustrated as an example. More or fewer dielectric layers 152 and metallization layer(s) 154 than illustrated may be formed by performing the previously described steps any desired quantity of times.

Other variations of the back-side redistribution structure 160 are contemplated. For example, some of the dielectric layers 152 may be formed of an encapsulant, such as a molding compound, epoxy, or the like. A metallization layer 154 may be formed by plating a conductive via from a conductive line. A dielectric layer 152 may be formed by encapsulating such a metallization layer 154. Any desired stack of materials may be used for the dielectric layers 152.

UBMs 156 may be formed through the lower dielectric layer 152 of the back-side redistribution structure 160. The UBMs 156 are physically and electrically coupled to the lower metallization layer 154 of the back-side redistribution structure 160. The UBMs 156 each include conductive vias and conductive bumps. The conductive vias extend through the lower dielectric layer 152, and the conductive bumps extend along the lower dielectric layer 152. The UBMs 156 may be formed of the same material(s) as the metallization layer(s) 154. In some embodiments, the UBMs 156 have a different size than the metallization layer(s) 154.

In some embodiments, the interposer wafer 100 may undergo subsequent processing steps. For example, the package components 200 may be singulated to form discrete package components 200. The singulation process may include sawing, dicing, or the like through the interposer wafer 100 to singulate the package regions 100P from one another. As discussed in greater detail below, one or more package components 200 will be attached to a reconstituted package substrate 300 to form an integrated circuit package 400.

FIGS. 6-13 are views of intermediate stages in the manufacturing of a reconstituted package substrate 300, in accordance with some embodiments. For example, a substrate core 302 may be provided, and through substrate vias 306 (e.g., through glass vias 306) may be formed through the substrate core 302. In addition, redistribution structures may be formed on opposite sides of the substrate core 302 to form a component substrate 330. The component substrate 330 may then be singulated into discrete singulated component substrates 330, and a plurality of the singulated component substrates 330 are attached to a carrier in order to be formed into a reconstituted package substrate 300.

In FIG. 6, a substrate core 302 is provided in wafer form which may include a core material 303 and a film 304 along surfaces of the core material 303. In some embodiments, the core material 303 may be formed of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 302 may be a SOI substrate. Generally, an SOI substrate includes a layer of a semiconductor material such as a layer of silicon, germanium, silicon germanium, or combinations thereof. In some embodiments, the core material 303 is an insulating material such as being a glass core (e.g., a fiberglass reinforced resin core). One example core material 303 is fiberglass resin such as FR4. Alternatives for the core material 303 include bismaleimide-triazine (BT) resin, or alternatively, other printed circuit board (PCB) materials or films. Further, the film 304 may be a build up film such as Ajinomoto build-up film (ABF) or other laminates (e.g., copper film) which may be disposed on opposite surfaces of the core material 303.

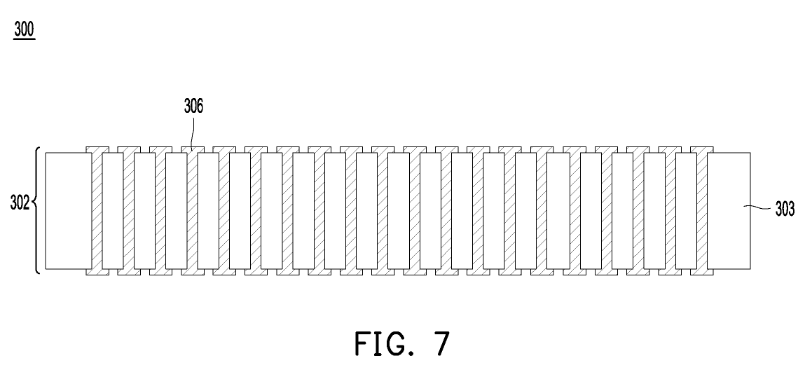

In FIG. 7, through substrate vias (TSVs) such as through glass vias (TGVs) 306 (e.g., for a glass substrate core 302) are formed through the substrate core 302, in accordance with some embodiments. For example, the substrate core 302 may be patterned to form through glass via openings (e.g., through the film 304 and the core material 303), which are then filled and patterned. The through glass via openings may be formed using any suitable method such as laser-drilling. One or more liner layers (not separately illustrated) may first be deposited over surfaces of the substrate core 302 including along inner sidewall surfaces of the through glass via openings. Formation of the liner layers may include re-laminating a same material as the film 304 (e.g., ABF or copper) over these exposed surfaces and/or depositing a seed layer (e.g., an electroless copper seed layer) over substrate core 302 and within the through glass via openings. A conductive material, such as copper, may then be deposited over the liner layers within the through glass via openings. Some excess portions of the liner layers and the conductive material outside of the through glass via openings may then be removed using a suitable method such as a grinding process. The remaining portions along major surfaces of the substrate core 302 may then be patterned so that the through glass vias 306 may be distinct electrical circuit elements.

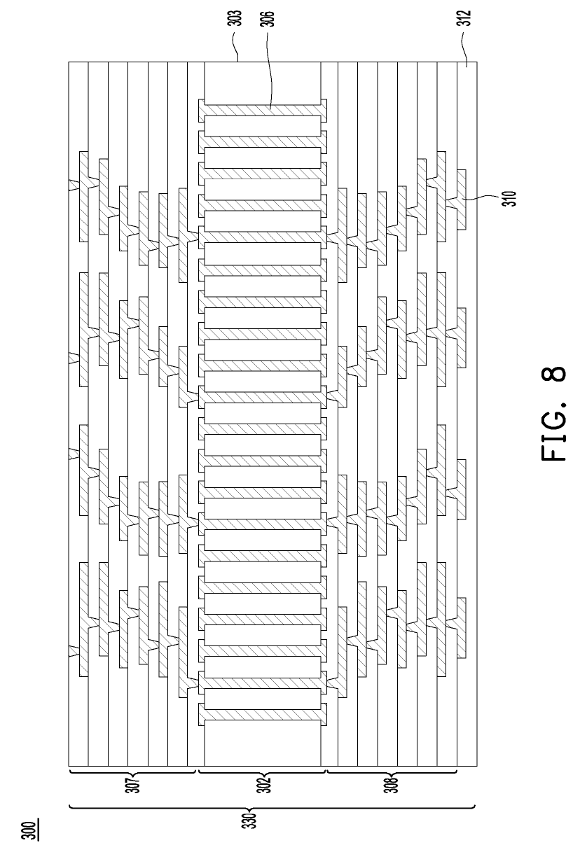

In FIG. 8, front side and back side redistribution structures 307, 308 are formed over opposite sides of the substrate core 302 to form component substrates 330 in wafer form. In some embodiments, metal pads 310 may be formed over the back side redistribution structure 308, and a passivation layer 312 may be formed over the metal pads 310. The structure may be referred to as a component substrate 330 in wafer form. The through glass vias 306 electrically couple the front side and the back side redistribution structures 307, 308. The front side and back side redistribution structures 307, 308 may be formed similarly as described above in connection with the front side and/or the back side redistribution structures 130, 160 of the package component 200. In some embodiments, the metal features (not separately labeled) may comprise a suitable conductive material (e.g., copper) and the dielectric layers (not separately labeled) may comprise a suitable insulating material (e.g., ABF).

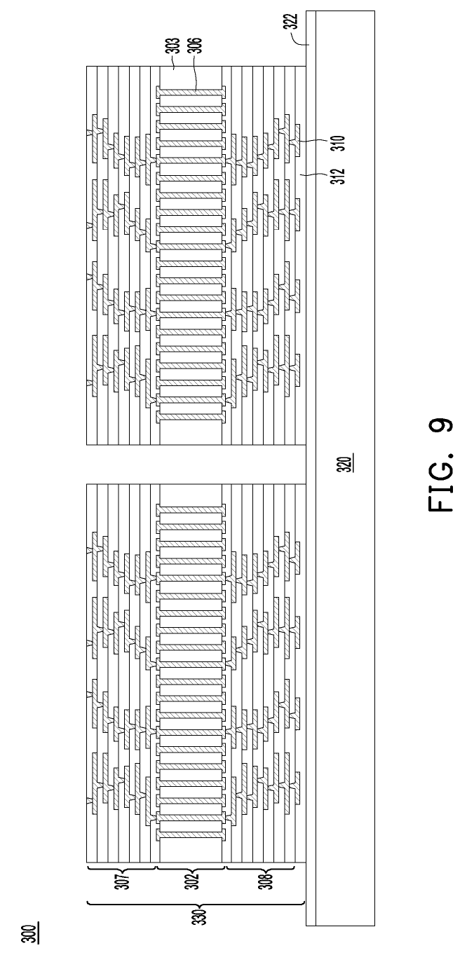

In FIG. 9, the component substrates 330 are singulated and a plurality of the singulated component substrates 330 are attached to a carrier 320, in accordance with some embodiments. For example, the carrier 320 may comprise a suitable material such as a type of glass, such as a silica (e.g., fiberglass and/or resin). In addition, an adhesive layer 322 may be disposed along an upper surface of the carrier 320. The component substrates 330 may be placed on the adhesive layer 322 along the carrier 320 using, e.g., a pick-and-place tool. As illustrated, gaps may laterally separate adjacent component substrates 330.

In some embodiments, an acceptance testing process (e.g., a wafer acceptance testing) may be performed on the component substrates 330. Note that the testing may be performed before or after singulation of the component substrates 330. The testing identifies the component substrates 330 which meet desired performance standards. Those component substrates 330 which pass may be referred to as known good substrates (KGS). The KGS among the component substrates 330 are used to form the reconstituted package substrate 300, while the others may be discarded or repurposed.

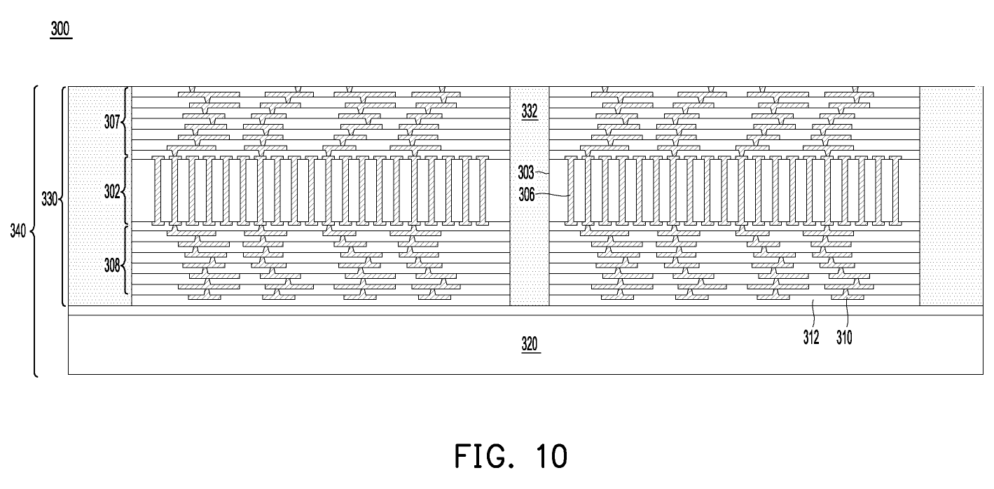

In FIG. 10, a gap-filling material 332 is deposited over the carrier 320 and around and between the component substrates 330. As illustrated, the gap-filling material 332 substantially fills the gaps between adjacent component substrates 330. Deposition of the gap-filling material 332 incorporates the component substrates 330 into a reconstituted package wafer 340. The gap-filling material 332 may be a suitable molding material, such as a polymer, resin, or the like. After depositing the gap-filling material 332, a planarization process may be performed so that upper surfaces of the gap-filling material 332 and the component substrates 330 are substantially level.

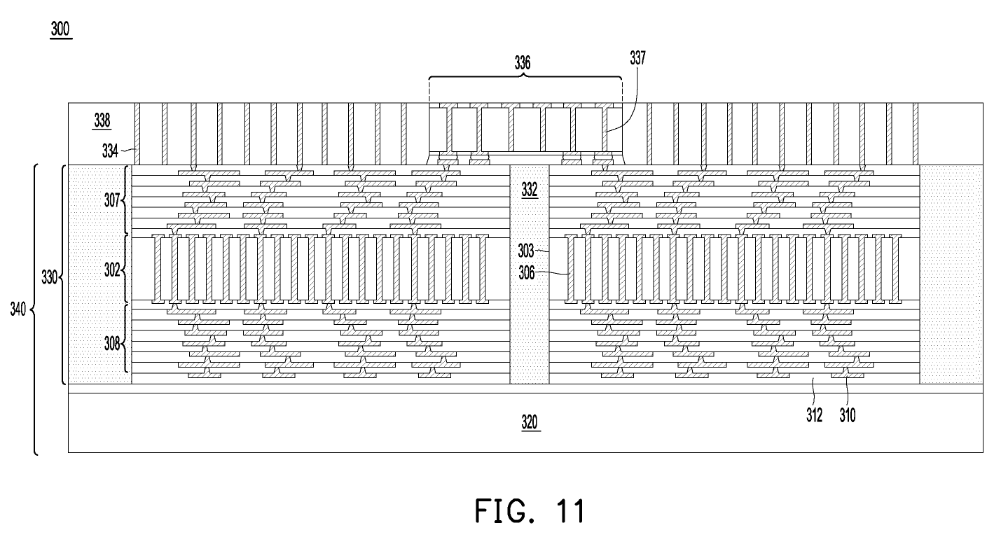

In FIG. 11, an interposer layer is formed over the component substrates 330 and the gap-filling material 332, in accordance with some embodiments. For example, metal pillars 334 may be formed over and electrically connected to some or all of the component substrates 330. The metal pillars 334 may comprise a suitable conductive material, such as copper. In addition, one or more interconnection dies 336 (e.g., bridge dies) may be attached over the component substrates 330 of the reconstituted package wafer 340. As illustrated, some of the interconnection dies 336 may be attached over and electrically connected to more than one of the component substrates 330. The interconnection dies 336 may include passive devices such as surface mount devices (SMDs), 2-terminal integrated passive devices (IPDs), multi-terminal IPDs, or the like, or integrated voltage regulators (IVRs).

In some embodiments, the interconnection dies 336 are bonded to the component substrates 330 of the reconstituted package wafer 340 in a face-down layout (e.g., active side down) and may be electrically connected to one or more of the component substrates 330. As illustrated, some of the interconnection dies 336 may be connected to two of the singulated component substrates 330. In addition, some of the interconnection dies 336 may comprise through substrate vias which extend toward a back-side of the interconnection dies 336.

After forming the metal pillars 334 and attaching the interconnection dies 336, a molding polymer 338 is formed over and around the metal pillars 334 and the interconnection dies 336, in accordance with various embodiments. In addition, the molding polymer 338 may be planarized to expose upper surfaces of the metal pillars 334 and through substrate vias 306 of the interconnection dies 336. The metal pillars 334 extending through the molding polymer 338 may also be referred to as through interposer vias (TIVs).

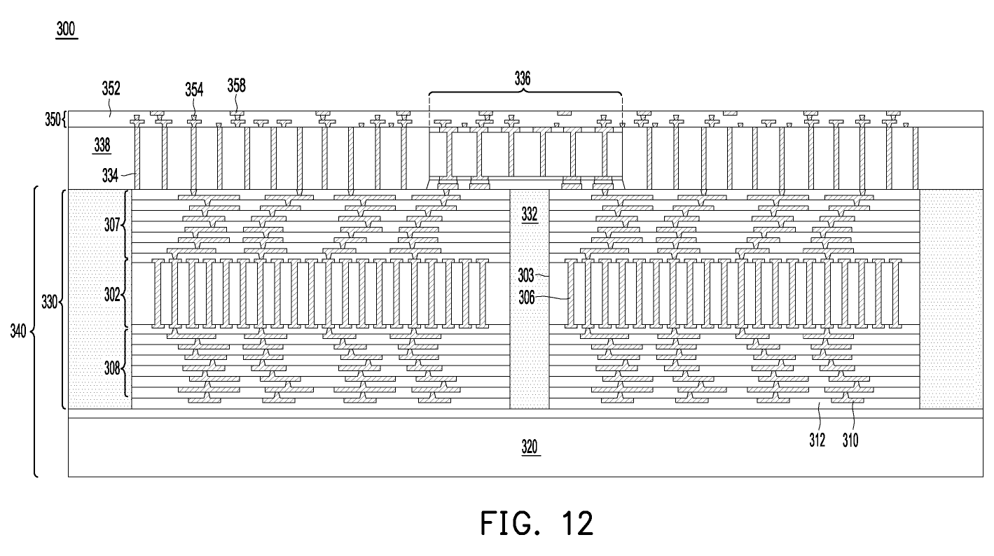

In FIG. 12, an interconnect structure such as a redistribution structure 350 may be formed over the metal pillars 334, the interconnection dies 336, and the molding polymer 338. For example, the redistribution structure 350 may include metallization layers 354 (e.g., comprising metal traces and metal vias) embedded in one or more dielectric layers 352. As illustrated, an uppermost level of the redistribution structure 350 may comprise a bonding layer. The bonding layer may include metal pads or bond pads 358 embedded in a bonding layer. The bond pads 358 will facilitate subsequent attachment of other package components.

In FIG. 13, one or more of package components 200 are attached to a reconstituted package substrate 300 to form integrated circuit package 400, in accordance with some embodiments. Note that the package components 200 and the reconstituted package substrate 300 may be formed similarly as described above in connection with the package components 200 and the reconstituted package substrate 300, respectively, unless otherwise described or illustrated. Note that the package components 200 may include embodiments of the package component 200 as described above as well as an HBM, an SoIC, an IPD, a photonic die, or a power module.

The back-side redistribution structure 160 of the package component 200 may be attached to the bond pads 358 of the reconstituted package substrate 300 with solder bonds, such as with conductive connectors 158 disposed on the UBMs of the package component 200. The conductive connectors 158 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 158 may include a conductive material such as solder, copper, aluminum, gold, nickel, silver, palladium, tin, the like, or a combination thereof. In some embodiments, the conductive connectors 158 are formed by initially forming a layer of solder through evaporation, electroplating, printing, solder transfer, ball placement, or the like. Once a layer of solder has been formed on the structure, a reflow may be performed in order to shape the solder into the desired bump shapes of the conductive connectors 158.

Attaching the reconstituted package substrate 300 to the back-side redistribution structure 160 may include placing the reconstituted package substrate 300 on the back-side redistribution structure 160 and reflowing the conductive connectors 158. The reconstituted package substrate 300 may be placed on the back-side redistribution structure 160 using, e.g., a pick-and-place tool. In some embodiments, a thermal compression bonding process may be used. For example, the conductive connectors 158 are reflowed to attach the bond pads 358 to the UBMs 156 of the back-side redistribution structure 160, and a bond head (not specifically illustrated) may apply heat while pressing the package component 200 toward the reconstituted package substrate 300. The conductive connectors 158 connect the interposer 240, including metallization layers of the back-side redistribution structure 160, to the reconstituted package substrate 300, including metallization layers of the substrate core 302. Thus, the reconstituted package substrate 300 is electrically connected to the integrated circuit devices 150 in of the package component 200.

Additionally, passive devices (not specifically illustrated) may be attached to the reconstituted package substrate 300 at any suitable time, whether before or after the respective singulation process or after attachment of the reconstituted package substrate 300 and the package components 200. For example, the passive devices may be attached to the package component 200, such as to the same surface of the back-side redistribution structure 160 as the metal pads 156 and the conductive connectors 158. Additionally or alternatively, the passive devices may be attached to the reconstituted package substrate 300, such as to the same surface of the reconstituted package substrate 300 as the bond pads 358. The passive devices may include capacitors, resistors, inductors, the like, or a combination thereof. The passive devices may be surface mount devices (SMDs), 2-terminal integrated passive devices (IPDs), multi-terminal IPDs, or the like.

In some embodiments, an encapsulant 408 is formed around the various components. After formation, the encapsulant 408 laterally encapsulates the passive devices (if present), the conductive connectors 158, and the redistribution structure 350. The encapsulant 408 may be formed between the reconstituted package substrate 300 and the back-side redistribution structure 160 of the package component 200. The encapsulant 408 may be a molding compound, epoxy, or the like. The encapsulant 408 may be applied by compression molding, transfer molding, or the like. The encapsulant 408 may be applied in liquid or semi-liquid form and then subsequently cured.

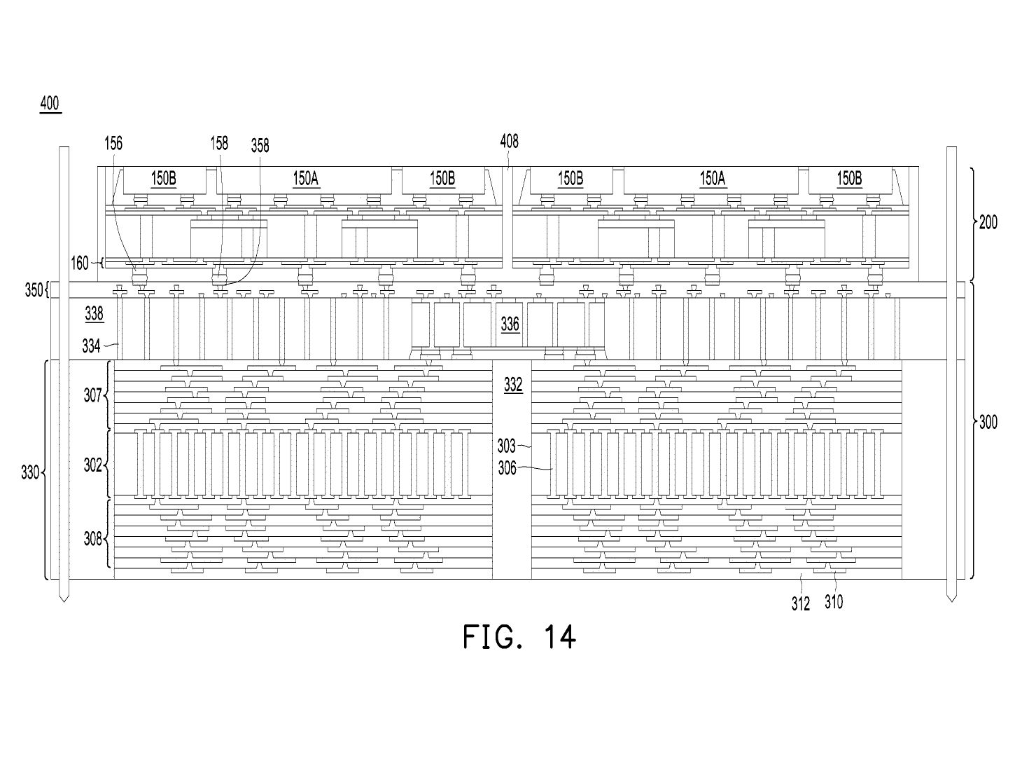

In FIG. 14, the carrier 320 is removed from the reconstituted package substrate 300, the adhesive layer 322 is removed, and the reconstituted package substrate 300 is sawed to singulate the integrated circuit packages 400, in accordance with some embodiments. For example, the carrier 320 may be de-bonded from the reconstituted package wafer by projecting a light such as a laser light or an UV light on the adhesive layer 322 so that the adhesive layer 322 decomposes under the heat of the light and the carrier 320 can be removed. Additionally, the singulation process is performed by cutting along scribe line regions between the package region 100P and adjacent package regions (not separately illustrated). The singulation process may include sawing, dicing, or the like. The singulation process singulates the package regions from one another, wherein each package region may include a plurality of package components 200. As a result of the singulation process, outer sidewalls of the redistribution structure 350 (e.g., the dielectric layers 352) are laterally coterminous (within process variations) with outer sidewalls of the gap-filling material 332 and the molding polymer 338.

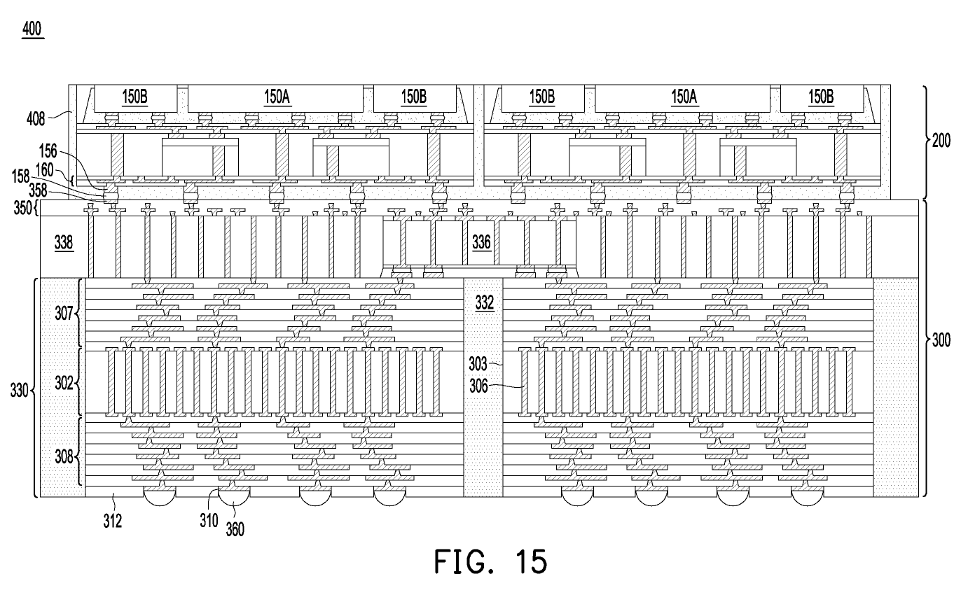

In FIG. 15, external connectors 360 may be formed on the metal pads 310, similarly as described above in connection with the conductive connectors 138, 158. For example, openings may be formed through the passivation layer 312 to expose the metal pads 310. The openings may be formed by a suitable process, such as using solder mask drilling and/or laser drilling. In some embodiments, the external connectors 360 are formed by initially forming a layer of solder through methods such as evaporation, electroplating, printing, solder transfer, ball placement, or the like. Once a layer of solder has been formed on the structure, a reflow may be performed in order to shape the external connectors 360 into desired bump shapes. Although not specifically illustrated, the external connectors 360 facilitate subsequent attachment of the integrated circuit package 400 into electronic devices as well as power and/or data transfer there-between.

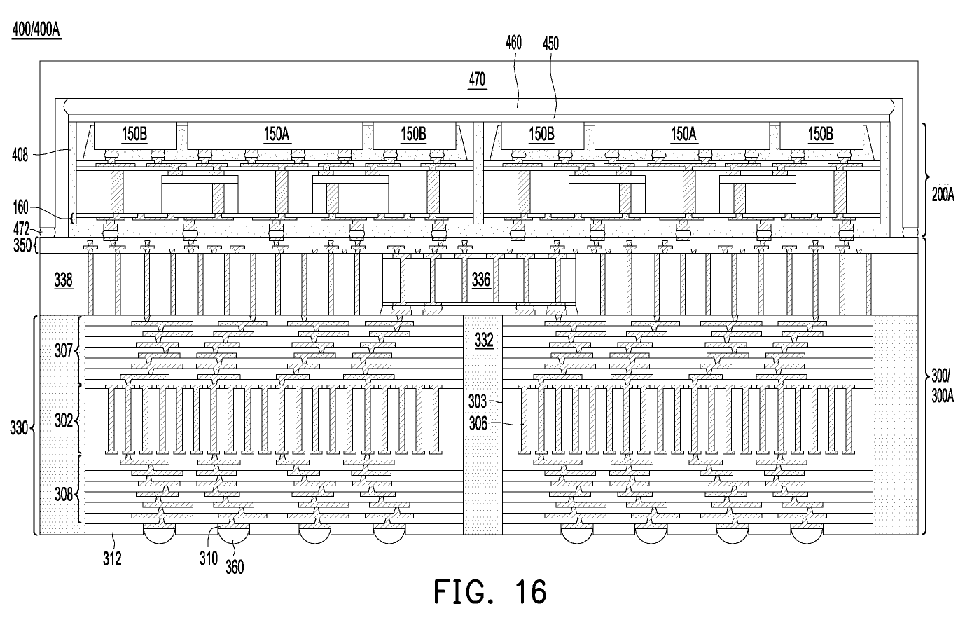

In FIG. 16, a metal layer 450 may be formed on the top surfaces of the package components 200 and the encapsulant 408. The metal layer 450 may be formed through a deposition process, such as Physical Vapor Deposition (PVD) or the like. The metal layer 450 may be a single layer or a composite layer comprising multiple sub-layers formed of different materials. The single layer or each of the multiple sub-layers of the metal layer 450 may be formed of a homogenous metallic material, a metal alloy, or the like. In some embodiments, the metal layer 450 is a single layer and comprises copper. In some embodiments, the metal layer 450 is a composite layer that comprises a plurality of sub layers. For example, the metal layer 450 may include an aluminum layer as a bottom sub-layer, a titanium layer as a middle sub-layer, and a copper layer as a top sub-layer. The metal layer 450 may be in contact with the silicon substrates in package components 200 and may dissipate the heat generated by the package components 200 during the operation of the integrated circuit package 400.

In addition, a thermal interface material (TIM) layer 460 is formed on the metal layer 450. The TIM layer 460 may comprise a material with high thermal conductivity, such as metal, metal alloy, or the like. In some embodiments, the TIM layer 460 comprises indium (In), tin (Sn), indium-silver (In-Ag) alloy, tin-bismuth (Sn-Bi) alloy, gallium (Ga), or the like. The TIM layer 460 may be formed by plating, such as electroplating or electroless plating, or the like. The metal layer 450 may be used as a seed layer during the plating process.

Still referring to FIG. 16, a lid 470 may be placed over the structure to serve, e.g., as a heat spreader. In some embodiments, the lid 470 may have a top portion and, optionally, a sidewall portion (e.g., a ring portion). The sidewall portion of the lid 470 may (e.g., continuously or discontinuously) loop around the package components 200 in a top-down perspective. In some embodiments, the lid 470 (e.g., the top portion) may comprise copper, indium, the like, or alloys thereof. An adhesive 472, such as an epoxy, may be on a bottom surface of the sidewall portion of the lid 470. The lid 470 may be attached to the reconstituted package substrate 300 by the adhesive 472. The lid 470 may be formed of a material with a high thermal conductivity, such as copper, stainless steel, or the like.

It should be further appreciated that each of the encapsulant 408, the metal layer 450, the TIM layer 460, and the lid 470 are option as appropriate. For example, in some embodiments, the integrated circuit package 400 may omit the encapsulant 408. In addition, the integrated circuit package may omit the metal layer 450, the TIM layer 460, and/or the lid 470.

In accordance with various embodiments, the integrated circuit package 400 includes one or more package components 200 attached to a reconstituted package substrate 300 as described above. In particular, formation of the reconstituted package substrate 300 includes forming an interposer layer (e.g., the metal pillars 334 and interconnection dies 336) formed over a plurality of component substrates 330 reconstituted into wafer form. In addition, a redistribution structure (e.g., an interconnect structure) may be formed to provide electrical routing and connectivity to the subsequently attached package components 200A.

Note that the integrated circuit package 400 as a device and the process steps for forming the device as discussed above may be representative of various additional embodiments disclosed below. In addition, it should be appreciated that the device and process steps as discussed above may be representative of an integrated circuit package 400A, in accordance with some embodiments. As such, the integrated circuit package 400A includes one or more package components 200A attached to a reconstituted package substrate 300A as described above.

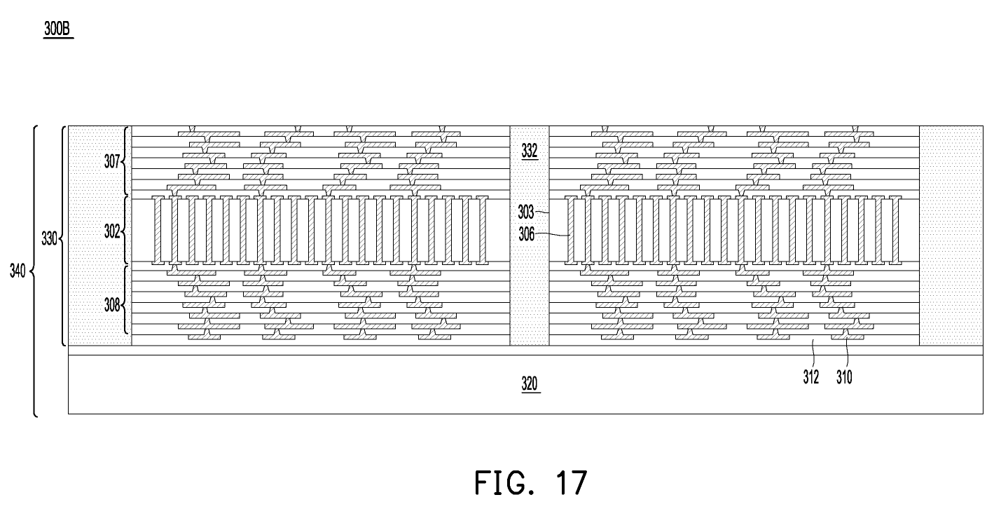

FIGS. 17-21 illustrate forming an integrated circuit package 400B with one or more package components 200B attached to a reconstituted package substrate 300B, in accordance with some embodiments. Note that features may be formed and processes may be performed similarly as described above in connection with analogous features of the package components 200B, the reconstituted package substrate 300B, and the integrated circuit package 400B, unless otherwise provided herein. In particular, the reconstituted package substrate 400B may be formed with the redistribution structure 350 formed over the singulated component substrates 330 while omitting formation of the metal pillars 334 and the interconnection dies 336 there-between, in accordance with some embodiments.

In FIG. 17, package substrates 330 are formed at the wafer level, singulated, and attached to a carrier 320, similarly as described above in connection with FIGS. 6-9. In addition, a gap-filling material 332 is deposited around and between the singulated package substrates 330, similarly as described above in connection with FIG. 10.

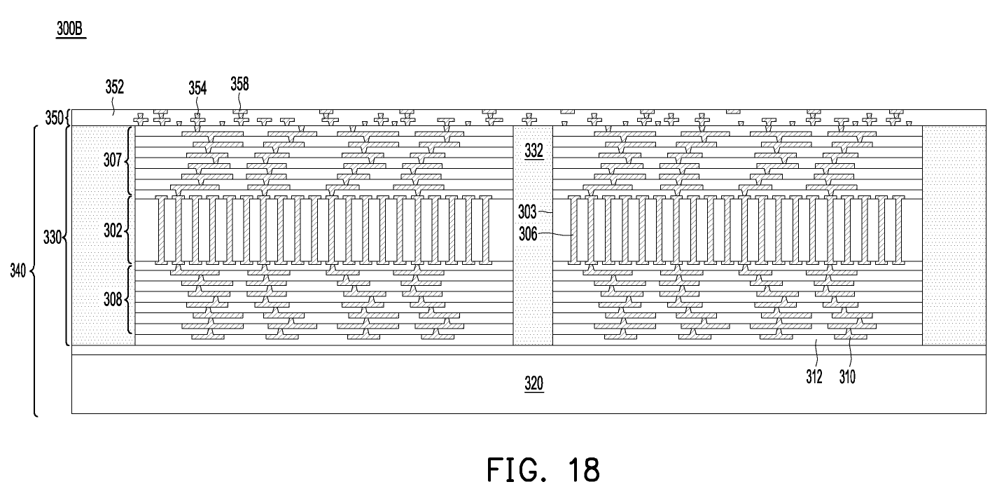

In FIG. 18, a redistribution structure 350 may be formed over the package substrates 330 and the gap-filling material 332 to form the reconstituted package wafer 300B, similarly as described above in connection with FIG. 12. For example, the redistribution structure 350 may include metallization layers 354 (e.g., metal traces and metal vias) embedded in one or more dielectric layers 352. As illustrated, an uppermost level of the redistribution structure 350 may comprise metal pads or bond pads 358.

As described and illustrated, the reconstituted package substrate 300B is similar to the reconstituted package substrate 300A, albeit with a few differences. For example, the reconstituted package substrate 300B omits the interposer layer (e.g., the metal pillars 334 and the interconnection dies 336 embedded in the molding polymer 338) provided in the reconstituted package substrate 300A. As such, the redistribution structure 350 of the reconstituted package substrate 300B may include a greater degree of electrical routing from the component substrates 330 to the overlying package components 200B. Moreover, as illustrated, some traces of the metallization layers 354 may extend over the lateral distance between adjacent package components 330 to electrically couple them to one another in addition to the overlying package components 200B.

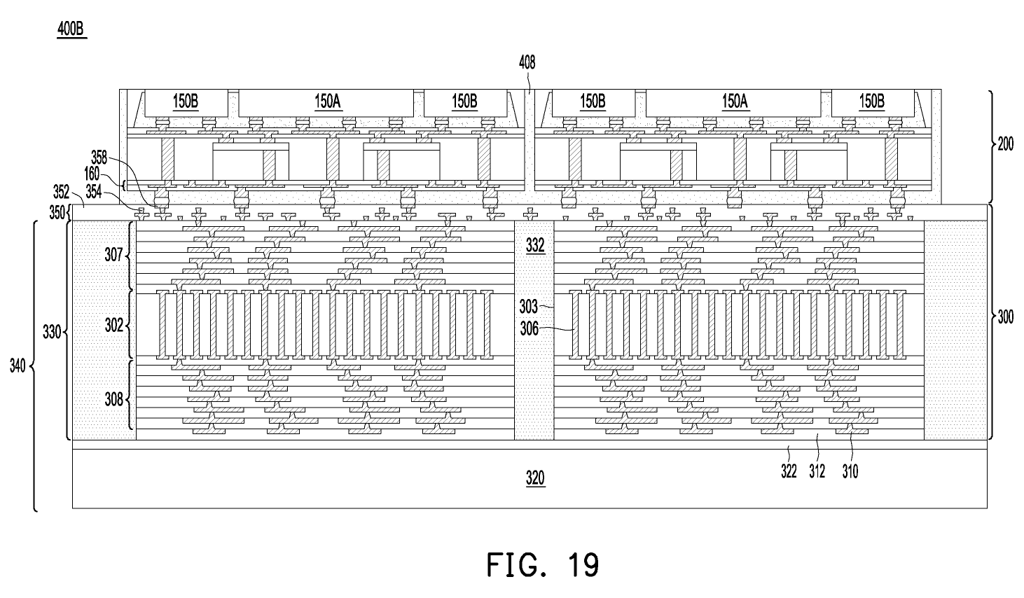

In FIG. 19, one or more of package components 200B are attached to the reconstituted package wafer 300B, similarly as described above in connection with FIG. 13. Note that the package components 200B may be formed similarly as described above in connection with the package components 200 (e.g., the package components 200A), unless otherwise described or illustrated.

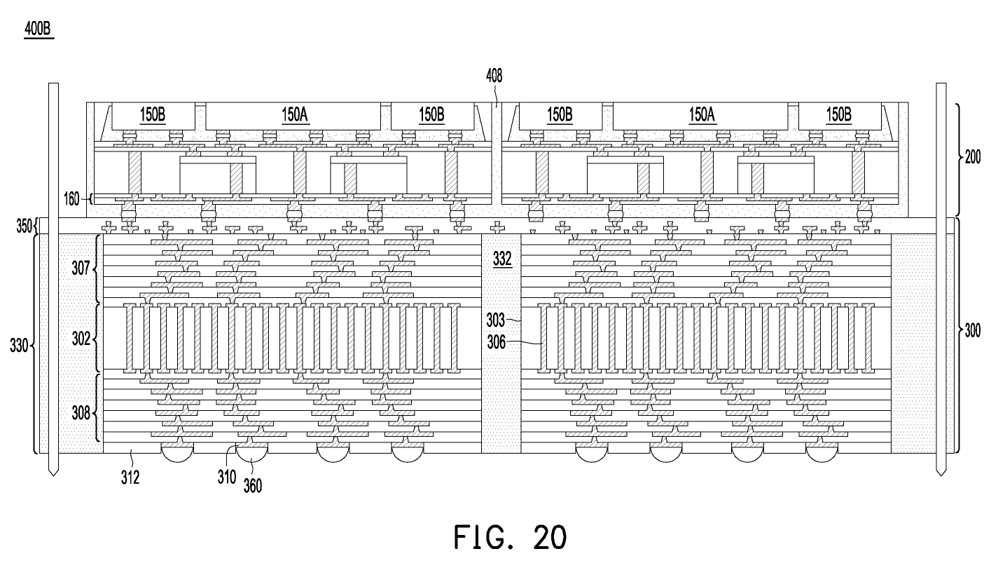

In FIG. 20, the carrier 320 is removed from the reconstituted package wafer 300B, the adhesive layer 322 is removed, and the reconstituted package wafer 300B is sawed to singulate the integrated circuit packages 200B, similarly as described above in connection with FIG. 14. For example, the carrier 320 may be de-bonded from the reconstituted package wafer by projecting a light such as a laser light or an UV light on the adhesive layer 322 so that the adhesive layer 322 decomposes under the heat of the light and the carrier 320 can be removed. Additionally, the singulation process is performed by cutting along scribe line regions between the package region 100P and adjacent package regions (not separately illustrated). The singulation process may include sawing, dicing, or the like. The singulation process singulates the package regions from one another, wherein each package region may include a plurality of package components 200B. As a result of the singulation process, outer sidewalls of the redistribution structure 350 (e.g., the dielectric layers 352) are laterally coterminous (within process variations) with outer sidewalls of the gap-filling material 332.

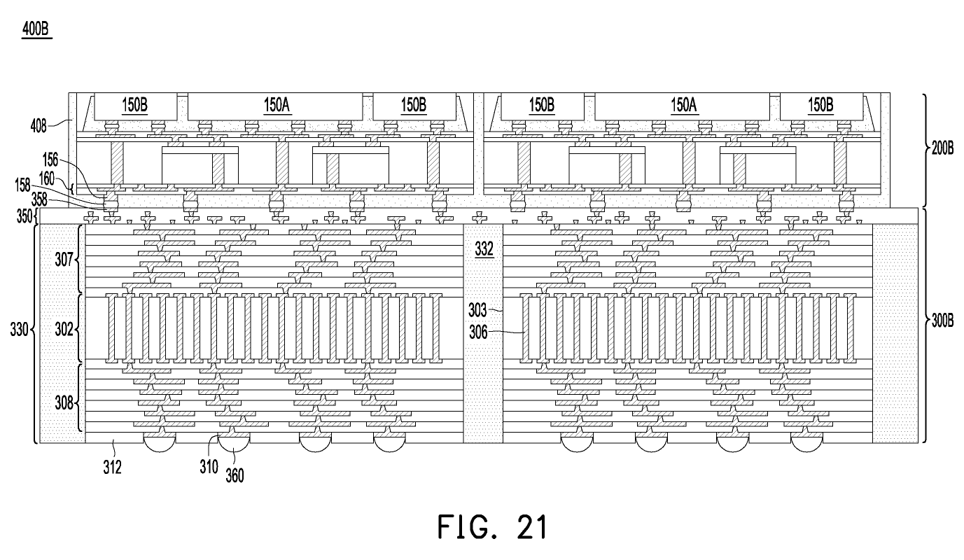

In FIG. 21, external connectors 360 may be formed on the metal pads 310, similarly as described above in connection with FIG. 15. For example, openings may be formed (e.g., by laser drilling) through the passivation layer 312 to expose the metal pads 310. In some embodiments, the external connectors 360 are formed by initially forming a layer of solder through methods such as evaporation, electroplating, printing, solder transfer, ball placement, or the like. Once a layer of solder has been formed on the structure, a reflow may be performed in order to shape the external connectors 360 into desired bump shapes. Although not specifically illustrated, the external connectors 360 facilitate subsequent attachment of the integrated circuit package 400B into electronic devices as well as power and/or data transfer there-between.

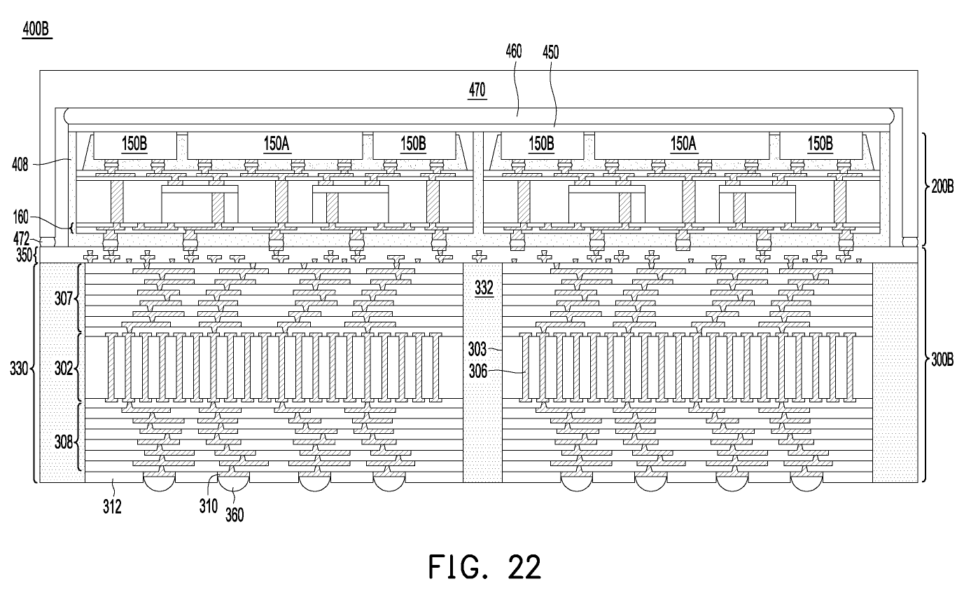

In FIG. 22, a metal layer 450, a TIM layer 460, and a lid 470 may be attached and/or formed over the package components 200B and the reconstituted package substrate 300B of the integrated circuit package 400B, similarly as described in connection with FIG. 16.

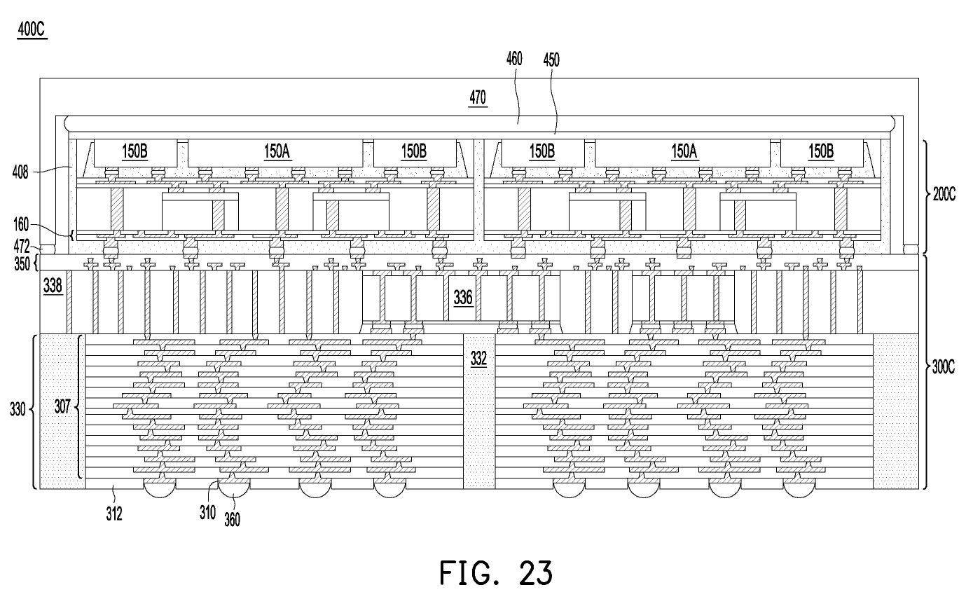

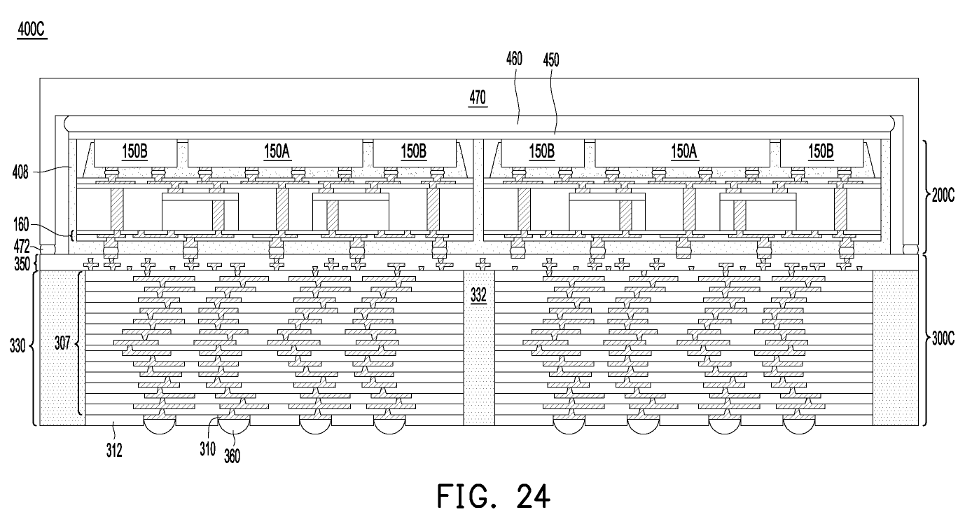

FIGS. 23 and 24 illustrate exemplary embodiments of an integrated circuit package 400C similar to the integrated circuit packages 400A, 400B described above, respectively. For example, the integrated circuit package 400C is formed with a coreless reconstituted package substrate 300C. In particular, the package components 330 are formed without a substrate core 302. As such, the component substrate 330 comprises only the redistribution structure 307. In some embodiments, layers of the redistribution structure 307 are formed in a front side direction as well as a back side direction. Similarly, the redistribution structure 307 may be formed by directly bonding two redistribution structures to one another. In other embodiments, an entirety of the redistribution structure 307 is formed in one direction (e.g., the front side direction).

In addition, FIG. 23 illustrates the integrated circuit package 400C wherein the reconstituted package substrate 300C includes an interposer layer, similarly as provided in the integrated circuit package 400A. Moreover, FIG. 24 illustrates the integrated circuit package 400C wherein the reconstituted package substrate 300C lacks an interposer layer, similarly as provided in the integrated circuit package 400B.

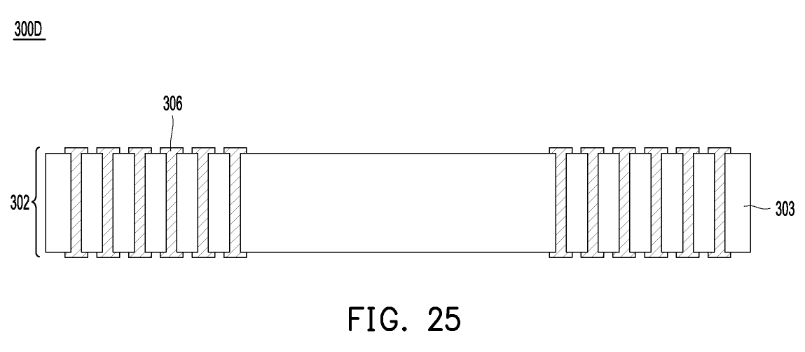

FIGS. 25-33 illustrate forming an integrated circuit package 400D with one or more package components 200D attached to a reconstituted package substrate 300D, in accordance with some embodiments. Note that features may be formed and processes may be performed similarly as described above in connection with analogous features of the package components 200 (e.g., package components 200A, 200B, and/or 200C), the reconstituted package substrate 300 (e.g., the reconstituted package substrates 300A, 300B, and/or 300C), and the integrated circuit package 400 (e.g., the integrated circuit packages 400A, 400B, and/or 400C), unless otherwise provided herein. In particular, the integrated circuit package 400D may include the reconstituted package substrate 300D being formed with passive devices embedded in the substrate core 302, in accordance with some embodiments.

In FIG. 25, a substrate core 302 is provided, which may be an insulating core such as a glass core (e.g., a fiberglass reinforced resin core), similarly as described above in connection with FIG. 6. In addition, through substrate vias such as through glass vias 306 are formed through the substrate core 302 and patterned, similarly as described above in connection with FIG. 7.

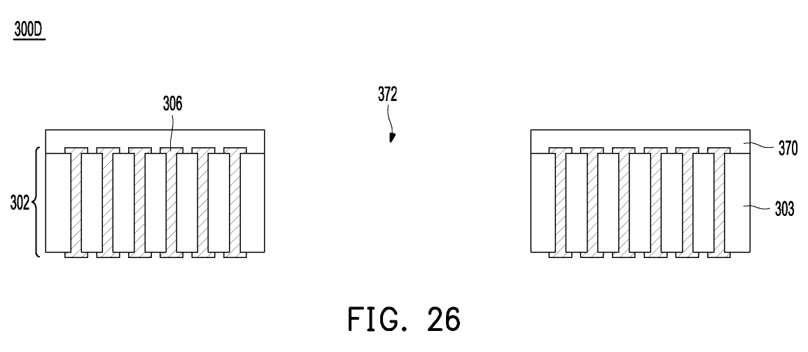

In FIG. 26, after forming and patterning the through glass vias 306, the substrate core 302 is applied to an adhesive tape 370, and one or more cavities 372 are etched through the substrate core 302 (and optionally through the adhesive tape 370) in locations which will subsequently house the passive devices.

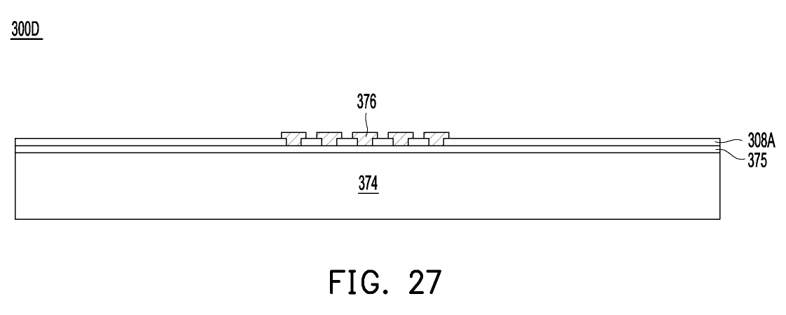

In FIG. 27, a glass carrier 374 is provided, and a primary layer 308A of a redistribution structure 307, 308 is formed over the glass carrier 374, in accordance with some embodiments. Although the primary layer 308A is illustrated as being part of the back side redistribution structure 308 similarly as described above in connection with FIG. 8, the primary layer 308A may instead be part of the front side redistribution structure 307. In some embodiments, an adhesive layer 375 may first be formed along a surface of the glass carrier 374. The primary layer 308A of the back side redistribution structure 308 is then formed over the adhesive layer 375. The primary layer 308A comprises a plurality of metal pads 376 (e.g., under-bump metallizations (UBMs)) at corresponding locations for the subsequently added passive devices.

For example, the adhesive layer 375 may be an epoxy-based thermal-release material, which loses its adhesive property when heated, such as a light-to-heat-conversion (LTHC) release coating. In other embodiments, the release layer 375 may be an ultra-violet (UV) glue, which loses its adhesive property when exposed to UV lights. In addition, the primary layer 308A may be formed similarly as described above in connection with the front side and/or the back side redistribution structures 130, 160 of the package component 200. In some embodiments, the metal features (not separately labeled) may comprise a suitable conductive material (e.g., copper) and the dielectric layers (not separately labeled) may comprise a suitable insulating material (e.g., ABF).

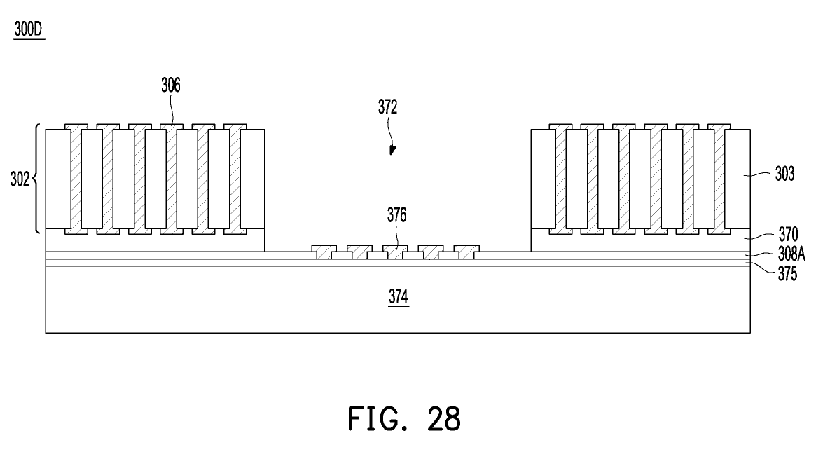

In FIG. 28, the substrate core 302 is attached to the primary layer 308A of the back side redistribution structure 308. In particular, the adhesive layer 370 along the substrate core 302 adheres the structures to one another. The attachment process may be performed using, e.g., a suitable wafer-to-wafer bonding process. As illustrated, some features of the primary layer 308A may remain exposed through the cavities 372 in the substrate core 302.

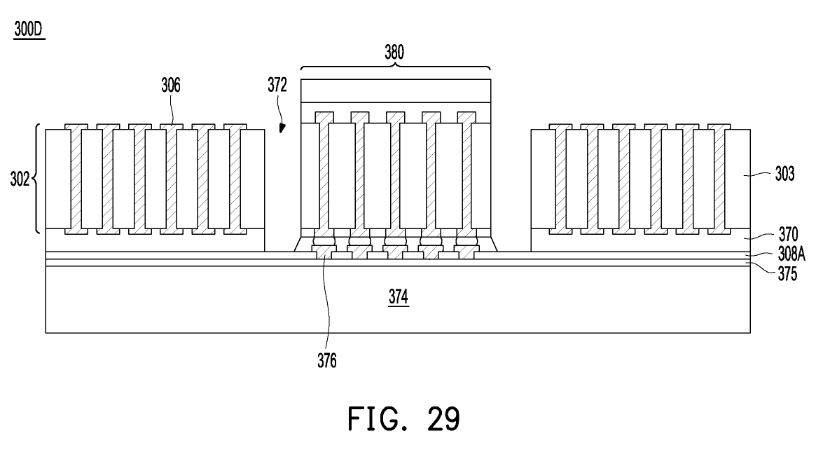

In FIG. 29, one or more passive devices 380 are attached to the metal pads 376 of the primary layer 308A within the one or more cavities 372 in the substrate core 302. For example, solder bumps disposed on external connectors along a first side of the passive devices 380 may be used to bond the passive devices 380. In addition, an underfill material may be dispensed around the solder bumps between the passive devices 380 and the primary layer 308A. Further, a removal process may be performed to remove back side portions of substrates of the passive devices 380. For example, the removal process may include a grinding process to remove some or all of silicon portions of the substrates. In some embodiments, the passive devices 380 may include integrated passive devices (IPDs), integrated voltage regulators (IVRs), and/or the like.

As illustrated, some of the passive devices 380 may include through substrate vias to allow for front side and back side electrical connectivity. In addition, some of the passive devices 380 may only have electrical connectivity along an active side (e.g., a front side). As such, some of those passive devices 380 may be placed active side down (e.g., face down) and coupled to the primary layer 308A of the back side redistribution structure. Further, others of those passive devices 380 may be placed active side up (e.g., face up) such that an inactive side (e.g., back side) of such passive devices 380 is adjacent to the primary layer 308A. Indeed, those locations of the primary layer 308A may not have conductive features for electrical connection to such passive devices 380.

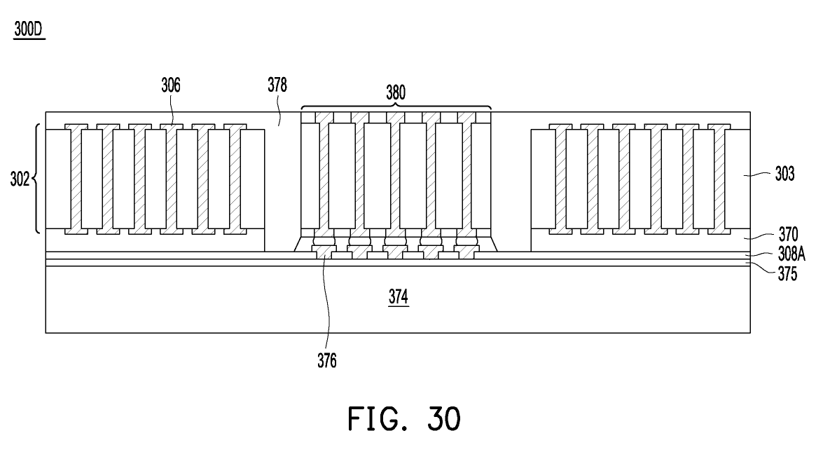

In FIG. 30, an ABF layer 378 is deposited to fill remainders of the cavities 372. A removal process may be performed to remove excess material of the ABF layer 378 and to remove additional portions of the substrates of the passive devices. For example, the removal process may include one or more grinding processes to remove more of the silicon portions of the substrates (if present) and some or all of any other layers (e.g., an oxide layer of a SOI substrate) to expose conductive features of the passive devices 380 (e.g., through substrate vias and/or bond pads). Following the removal process, the ABF layer 378 may be substantially level with these conductive features and any remaining portions of the substrates of the passive devices 380.

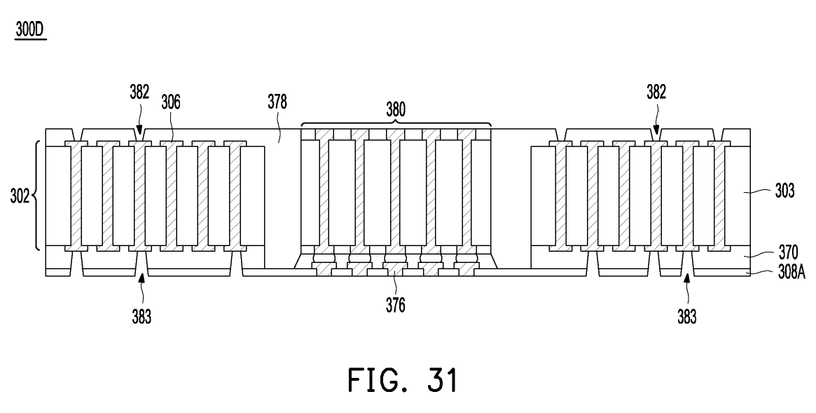

In FIG. 31, the glass carrier 374 is de-bonded from the substrate core 302, and via openings 382, 383 are formed on each side of the substrate core 302. For example, the via openings 382 may include drilling through the ABF layer 378 to expose the through substrate vias 306 over the front side of the substrate core 302. The glass carrier 374 may then be de-bonded from the substrate core 302 before forming the via openings 382 over the back side of the substrate core 302. In some embodiments (not specifically illustrated), the substrate core 302 (e.g., the via openings 382) may be cleaned, and the front side redistribution structure 307 is formed over the front side of the substrate core 302.

In accordance with some embodiments, the de-bonding may include projecting a light such as a laser light or an UV light on the adhesive layer 375 so that the adhesive layer 375 decomposes under the heat of the light and the glass carrier 374 can be removed. The substrate core 302 is then flipped over to prepare for processing of the back side of the substrate core 302. The substrate core 302 may be placed on a tape, a carrier substrate, or another suitable support structure (not separately illustrated) for subsequent processing.

The via openings 383 may include drilling through the dielectric material of the primary layer 308A as well as the adhesive tape 370 to expose the through substrate vias 306 over the back side of the substrate core 302. In some embodiments (not specifically illustrated), the substrate core 302 (e.g., the via openings 383) may be cleaned, and the back side redistribution structure 308 is completed over the primary layer 308A and the back side of the substrate core 302.

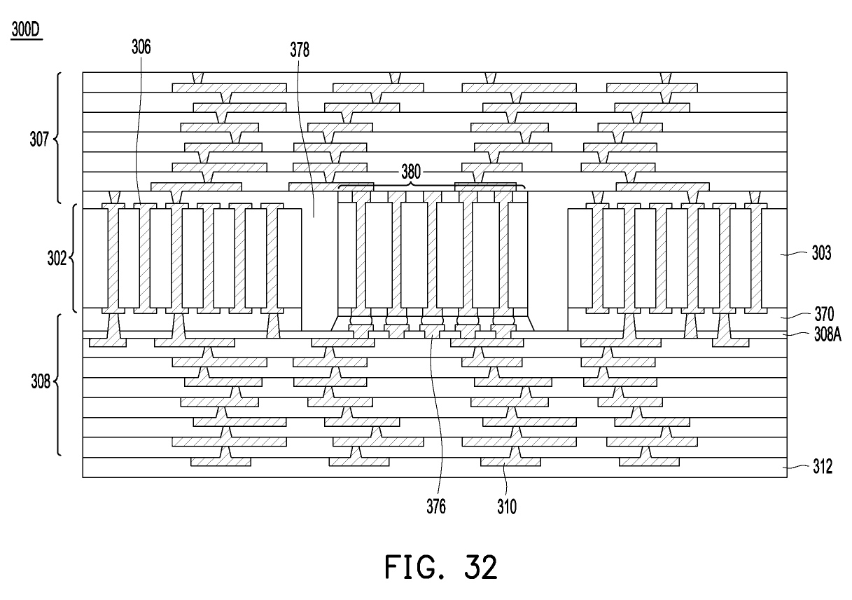

In FIG. 32, the front side redistribution structure 307 is formed over the front side of the substrate core 302 and through the via openings 382. In addition, the back side redistribution structure 308 is completed over the primary layer 308A, over the back side of the substrate core, and through the via openings 383, similarly as described above in connection with FIG. 8. As discussed above, metal features (not separately labeled) may comprise a suitable conductive material (e.g., copper) and dielectric layers (not separately labeled) may comprise a suitable insulating material (e.g., ABF). Note that the front side and back side redistribution structures 307, 308 (and their component features) may be formed in any suitable order. In addition, the front side redistribution structure 307 may be formed after forming the via openings 382 over the front side of the substrate core 302 and before removing the glass carrier 374. Further, the back side redistribution structure 308 may be formed after forming the via openings 383 over the back side of the substrate core 302 and before forming the front side redistribution structure 307 or before forming the via openings 382 over the front side of the substrate core 302.

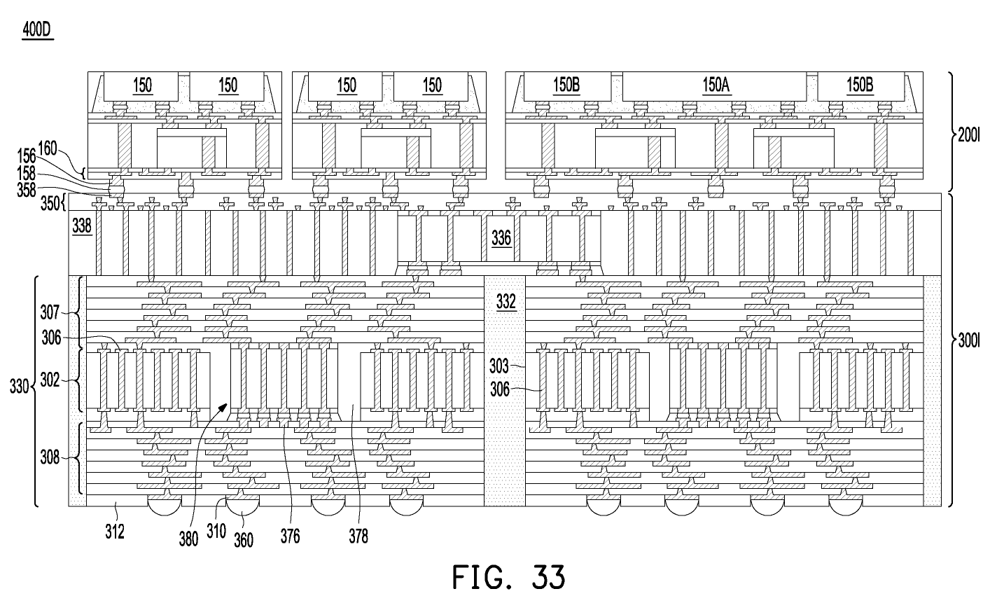

In FIG. 33, the component substrates 330 are converted into a reconstituted package substrate 300D, and the reconstituted package substrate 300D is incorporated into an integrated circuit package 400D. For example, the component substrate 330 in wafer form is singulated and converted into the reconstituted package substrate 300D, similarly as described above in connection with FIGS. 9-12. Note that the reconstituted package substrate 300D may include or omit the interposer layer. Package components 200D (similar to the package components 200 described above) are then attached to the reconstituted package substrate 300D, similarly as described above. In some embodiments, the encapsulant 408 around the package components 200D may be omitted, and the integrated circuit package 400D may then undergo subsequent processing similarly as described above.

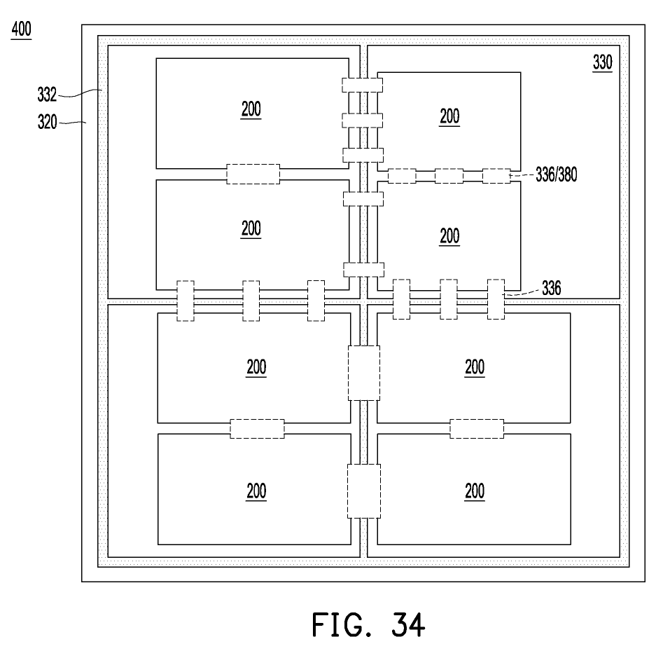

FIG. 34 illustrates a plan view (e.g., a top-down view) of an integrated circuit package 400, in accordance with any of the embodiments described above or below. For example, the integrated circuit package 400 may include a reconstituted package substrate 300 which comprises two or more component substrates 330 (e.g., four, six, nine component substrates 330, or any suitable number). As illustrated, interconnection dies at various levels of the integrated circuit package 400 may assist interconnectivity between the package components 200 with one another as well as with the component substrates 330. For example, the interconnection dies that are disposed over the lateral distances between adjacent component substrates 330 may be the interconnection dies 336 attached within the interposer layer. In addition, the interconnection dies that are disposed within a footprint of a component substrate 330 may be the interconnection dies 336 of the interposer layer or the interconnection dies 380 attached within the substrate core 302. However, any suitable combinations of the above-described interconnection dies may be used.

The plan view illustrates benefits of forming the reconstituted package substrate 300 as discussed herein. For example, the reconstituted package substrate 300 may be formed to be substantially larger (e.g., multiple times larger) than a package substrate formed with a single continuous component substrate. The reconstituted package substrate 300 is less vulnerable to warpage during various processing steps, such as attachment of the package components 200. Indeed, the reconstituted package substrate 300 is able to support a greater number of package components 200 (and other devices, such as HBM dies) as well as package components 200 of a greater size (e.g., footprint). As illustrated, the package components 200 may come in a variety of sizes, such as 3.5x and 5x reticles. As such, the integrated circuit package 400 may support package components 200 totaling greater than 30 reticles. For example, in the illustrated embodiment, the integrated circuit package 400 can be formed with side lengths of about or greater than 200 mm, and each of the component substrates 330 may have side lengths of about or great than 120 mm. Moreover, one or more integrated circuit packages 400 may be formed within a single layer, such that the integrated circuit packages 400 collectively have side lengths of about or greater than 400 mm, which can be supported by a carrier 320 with side lengths of about or greater than 500 mm.

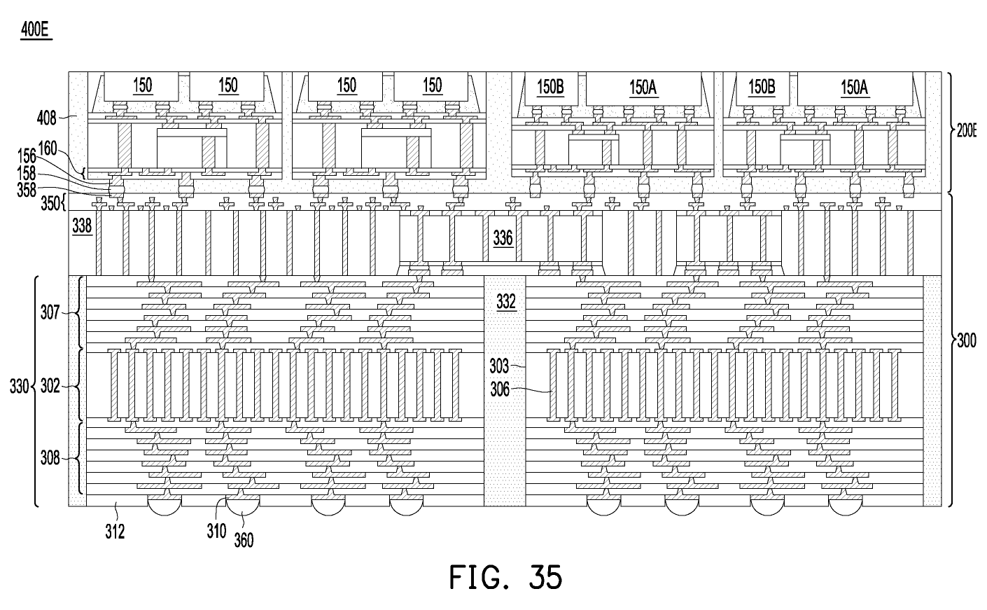

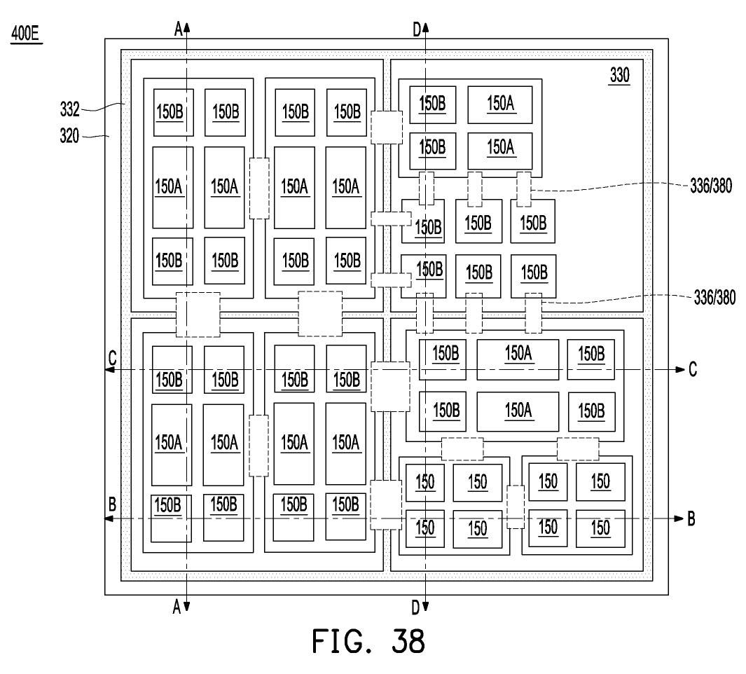

FIGS. 35-37 illustrate various cross-sections of additional exemplary embodiments of integrated circuit packages 400E. FIG. 38 illustrates a plan view (e.g., a top-down view) of a hypothetical integrated circuit package 400E which includes a combination of the embodiments illustrated in FIGS. 35-37. Note that each of the integrated circuit packages 400E is illustrated with reconstituted package substrates 300E similar to the reconstituted package substrate 300A of FIG. 22. However, any of the other embodiments of reconstituted package substrates 300 (e.g., the reconstituted package substrates 300B, 300C) may be utilized. In addition, other integrated circuit packages 400 may include package components 200 that are also represented in FIG. 38, wherein the integrated circuit package 400E includes consistent embodiments of the reconstituted package substrates 300. Although the metal layer 450, the TIM layer 460, and the lid 470 are omitted from the illustrations for simplicity, each of these features may be included in the integrated circuit package 400E, similarly as described above in connection with FIG. 16.

In FIG. 35, a cross-sectional view of an exemplary embodiment of the integrated circuit package 400E includes pluralities of the package components 200E having a greater than one-to-one correspondence with each of the illustrated component substrates 330 of the reconstituted package substrate 300E. As illustrated, the encapsulant 408 is continuous between adjacent package components 200E disposed directly over a same component substrate 330. In addition, the encapsulant 408 may also be continuous between adjacent package components 200E disposed directly over different component substrates 330 (as illustrated) – or discontinuous (not specifically illustrated).

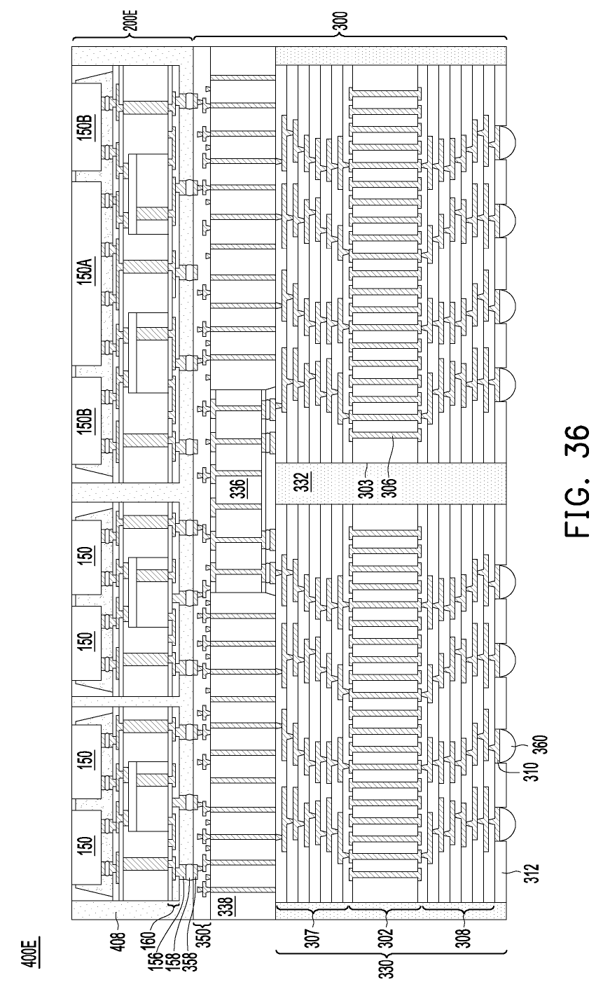

In FIG. 36, a cross-sectional view of an exemplary embodiment of the integrated circuit package 400E includes some of the illustrated package components 200E having a one-to-one correspondence with the associated component substrates 330 of the reconstituted package substrate 300E. Such package components 200E may therefore be larger in size and occupy a greater fraction of the footprint of the corresponding component substrate 330.

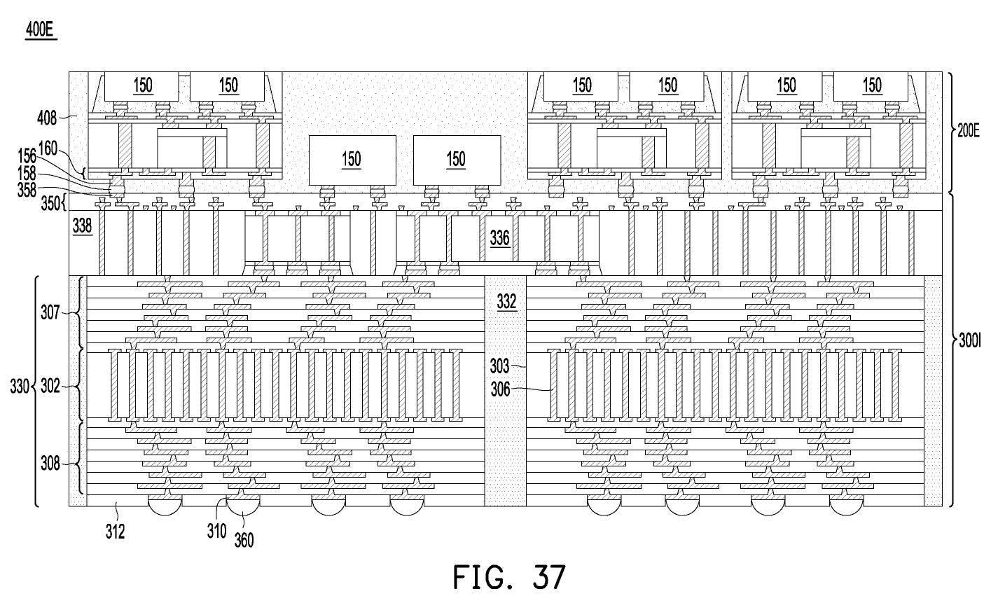

In FIG. 37, a cross-sectional view of an exemplary embodiment of the integrated circuit package 400E includes some integrated circuit devices 150 being attached directly to the reconstituted package substrate 300E without an interposer 100 there-between. For example, these integrated circuit devices 150 may include memory devices (e.g., HBM dies) or logic devices. Being attached without being incorporated into a package component 200E, these integrated circuit devices 150 may rely on interconnectivity within the reconstituted package substrate 300E.

In FIG. 38, illustrates a plan view (e.g., a top-down view) of a hypothetical integrated circuit package 400E, showing a layout of various embodiments of the package components 200E attached to the reconstituted package substrate 300E. In particular, a hypothetical combination of the embodiments illustrated in FIGS. 35-37 is illustrated. For example, the A-A cross-section may represent any of the integrated circuit packages 400A, 400B, 400C, and 400D. The B-B cross-section may represent the integrated circuit package 400E illustrated in FIG. 35. The C-C cross-section may represent the integrated circuit package 400E illustrated in FIG. 36. The D-D cross-section may represent the integrated circuit package 400E illustrated in FIG. 37.

Embodiments may achieve advantages. Integrated circuit packages 400 may be formed with larger package substrates which experience less warpage. For example, the package substrate may be reconstituted package substrates which include a plurality of component substrates embedded in a gap-filling polymer. As a result, a greater number of passive devices may be incorporated into the reconstituted package substrates, and a great number of package components may be attached to the reconstituted package substrates. The reduced warpage results in the integrated circuit packages being manufactured at a greater yield and functioning at an improved performance, better reliability, and increased longevity.

In an embodiment, a method includes forming a package component, the package component comprising: an interposer comprising a first redistribution structure; a plurality of integrated circuit dies attached to a first side of the first redistribution structure; forming a package substrate, forming the package substrate comprising: forming a second redistribution structure and a third redistribution structure over opposite sides of a substrate core; singulating the substrate core to form a plurality of component substrates; attaching a first component substrate and a second component substrate to a carrier, the first component substrate and the second component substrate being laterally displaced from one another by a gap; and forming a bonding layer over the first component substrate and the second component substrate; attaching the package component to the package substrate; and forming external connectors over the package substrate, the external connectors being configured to electrically couple a signal routing, a power routing, or a ground routing of the plurality of integrated circuit dies to an additional package component. In another embodiment, forming the bonding layer comprises forming a fourth redistribution structure over the first component substrate and the second component substrate, and wherein the fourth redistribution structure comprises the bonding layer. In another embodiment, the method further includes, before forming the fourth redistribution structure, forming an interconnection layer over the first component substrate and the second component substrate, wherein the interconnection layer comprises an interconnection die and a through interposer via embedded in a molding polymer. In another embodiment, the interconnection die electrically couples the first component substrate to the second component substrate. In another embodiment, the package component is electrically connected to the first component substrate and the second component substrate. In another embodiment, the method further includes forming the substrate core, wherein forming the substrate core comprises: forming a through glass via through a glass core; forming an opening through the glass core; and placing a passive device within the opening of the glass core. In another embodiment, the passive device electrically couples the second redistribution structure to the third redistribution structure, and wherein the through glass via electrically couples the second redistribution structure to the third redistribution structure.

In an embodiment, a method includes forming a first set of through substrate vias (TSVs) and a second set of TSVs through a substrate core; forming a first redistribution structure over the first set of TSVs; forming a second redistribution structure over the second set of TSVs, the second redistribution structure being electrically isolated from the first redistribution structure and the first set of TSVs; performing a singulation process to form a first component substrate and a second component substrate, wherein the first component substrate comprises a first portion of the substrate core, the first set of TSVs, and the first redistribution structure, and wherein the second component substrate comprises a second portion of the substrate core, the second set of TSVs, and the second redistribution structure; attaching the first component substrate and the second component substrate to a carrier, the first component substrate being laterally displaced from the second component substrate by a gap; filling the gap with a molding material; forming a third redistribution structure over the first component substrate and the second component substrate, wherein after forming the third redistribution structure, the first component substrate and the second component substrate are electrically connected; and attaching package components to the third redistribution structure, wherein each of the package components comprises a plurality of integrated circuit dies disposed over an interposer. In another embodiment, the method further includes, before forming the third redistribution structure: forming metal pillars directly over the first redistribution structure and the second redistribution structure; attaching a first interconnection die directly over the molding material, the first redistribution structure, and the second redistribution structure; and forming a molding polymer around the metal pillars and the first interconnection die. In another embodiment, the first interconnection die is electrically coupled to the first redistribution structure, the second redistribution structure, and the third redistribution structure. In another embodiment, the method further includes, before forming the first redistribution structure and the second redistribution structure: forming a first cavity and a second cavity through the substrate core; attaching the substrate core to a redistribution layer; attaching a first passive device to the redistribution layer within the first cavity; and attaching a second passive device to the redistribution layer within the second cavity. In another embodiment, attaching the first passive device comprises electrically coupling the first passive device to the redistribution layer, and wherein attaching the second passive device comprises adhering an inactive side of the second passive device to the redistribution layer. In another embodiment, the method further includes forming an encapsulant around and between the package components, wherein the encapsulant is continuous.

In an embodiment, a semiconductor device includes a package substrate comprising: a first component substrate comprising a first redistribution structure; a second component substrate comprising a second redistribution structure, the second component substrate being laterally displaced from the first component substrate; a molding material disposed between the first component substrate and the second component substrate; and a third redistribution structure disposed over the first component substrate and the second component substrate, the third redistribution structure being electrically connected to both the first component substrate and the second component substrate; and a first package component attached to the third redistribution structure, the first package component comprising a first integrated circuit die disposed over a first interposer. In another embodiment, the first package component is electrically connected to both the first component substrate and the second component substrate. In another embodiment, the semiconductor device further includes a second package component attached to the third redistribution structure, wherein the second package component comprises a second integrated circuit die disposed over a second interposer. In another embodiment, a third interposer is disposed between the molding material and the third redistribution structure, wherein the third interposer comprises a third interconnection die, and wherein the third interconnection die is electrically coupled to the first redistribution structure, the second redistribution structure, and the third redistribution structure. In another embodiment, the first component substrate comprises a first glass core, and wherein a first passive device is contained within the first glass core. In another embodiment, the second component substrate comprises a second glass core, and wherein a second passive device is contained within the second glass core. In another embodiment, the first passive device comprises two electrically active sides, wherein the second passive device comprises a first side and a second side being opposite of one another, wherein the first side is electrically active, and wherein the second side is electrically inactive.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first redistribution structure and a second redistribution structure over opposite sides of a substrate core, the substrate core comprising through substrate vias electrically coupling the first redistribution structure to the second redistribution structure;
singulating the substrate core to form a plurality of component substrates comprising a first component substrate and a second component substrate;
adhering the first component substrate and the second component substrate to a carrier, the first component substrate being laterally separated from the second component substrate by a gap;
filling the gap with a gap-filling material to form a reconstituted package wafer; and
forming a third redistribution structure over the first component substrate, the second component substrate, and the gap-filling material, wherein after forming the third redistribution structure, the first component substrate and the second component substrate are electrically connected by the third redistribution structure.

2. The method of claim 1, further comprising, before forming the third redistribution structure: forming metal pillars over the first component substrate and the second component substrate; attaching an interconnection die over the gap-filling material, the first component substrate, and the second component substrate; and forming a molding polymer around the metal pillars and the interconnection die.

3. The method of claim 2, wherein the interconnection die electrically couples the first component substrate to the second component substrate.

4. The method of claim 2, wherein after forming the molding polymer, the metal pillars extend through the molding polymer as through interposer vias.

5. The method of claim 1, wherein the substrate core comprises a glass core, and wherein forming the through substrate vias comprises forming through glass vias through the glass core.

6. The method of claim 1, further comprising performing an acceptance testing process to identify known good substrates among the plurality of component substrates, wherein the first component substrate and the second component substrate are known good substrates.

7. The method of claim 1, further comprising attaching package components to the third redistribution structure, wherein a first package component of the package components comprises a plurality of integrated circuit dies over an interposer.

8. A semiconductor device comprising:
a first component substrate comprising a first substrate core, first through substrate vias through the first substrate core, and a first redistribution structure over the first substrate core;
a second component substrate laterally separated from the first component substrate, the second component substrate comprising a second substrate core, second through substrate vias through the second substrate core, and a second redistribution structure over the second substrate core;
a gap-filling material between the first component substrate and the second component substrate;
an interposer layer over the first component substrate and the second component substrate, the interposer layer comprising metal pillars electrically connected to the first component substrate and the second component substrate, an interconnection die electrically connected to both the first component substrate and the second component substrate, and a molding polymer around the metal pillars and the interconnection die, the metal pillars extending through the molding polymer as through interposer vias;
a third redistribution structure over the interposer layer, the third redistribution structure being electrically connected to the first component substrate and the second component substrate through the interposer layer; and
a package component attached to the third redistribution structure, the package component comprising an integrated circuit die over an interposer.

9. The semiconductor device of claim 8, wherein the interconnection die comprises a through substrate via extending toward a back-side of the interconnection die.

10. The semiconductor device of claim 8, wherein the first substrate core comprises a glass core, and wherein the first through substrate vias comprise through glass vias.

11. The semiconductor device of claim 8, wherein the package component is electrically connected to both the first component substrate and the second component substrate through the interposer layer and the third redistribution structure.

12. The semiconductor device of claim 8, wherein the interposer of the package component comprises a bridge die laterally encapsulated by an encapsulant and through vias extending through the encapsulant.

13. The semiconductor device of claim 8, further comprising a metal layer on a top surface of the package component, a thermal interface material layer on the metal layer, and a lid over the package component.

14. The semiconductor device of claim 8, wherein outer sidewalls of the third redistribution structure are laterally coterminous with outer sidewalls of the gap-filling material and the molding polymer.

15. A semiconductor device comprising:
a substrate core comprising a glass core;
through glass vias through the glass core;
a first redistribution structure over a first side of the substrate core;
a second redistribution structure over a second side of the substrate core opposite the first side, the through glass vias electrically coupling the first redistribution structure to the second redistribution structure, and the second redistribution structure comprising a primary layer having metal pads;
a first cavity and a second cavity through the substrate core;
a first passive device in the first cavity, an active side of the first passive device facing the primary layer and electrically coupled to a first metal pad of the metal pads;
a second passive device in the second cavity, an inactive side of the second passive device facing the primary layer; and
a build-up film layer filling a remainder of the first cavity and a remainder of the second cavity around the first passive device and the second passive device.

16. The semiconductor device of claim 15, further comprising a third passive device in a third cavity through the substrate core, wherein the third passive device comprises a through substrate via providing electrical connectivity between the first side and the second side of the substrate core.

17. The semiconductor device of claim 15, wherein the build-up film layer comprises an Ajinomoto build-up film.

18. The semiconductor device of claim 15, wherein the first passive device comprises one of an integrated passive device and an integrated voltage regulator.

19. The semiconductor device of claim 15, further comprising: a component substrate comprising the substrate core; a further component substrate laterally separated from the component substrate; a gap-filling material between the component substrate and the further component substrate; and a redistribution structure over the component substrate, the further component substrate, and the gap-filling material.

20. The semiconductor device of claim 15, wherein a surface of the build-up film layer is substantially level with a conductive feature of the first passive device.
